(19) United States
(12) Patent Application Publication
(10) Pub. No.: US 2025/0056966 A1
(43) Pub. Date: Feb. 13, 2025

(54) LIGHT EMITTING ELEMENT AND DISPLAY DEVICE INCLUDING THE SAME

(71) Applicant: Samsung Display Co., Ltd., Yongin-si (KR)

(72) Inventors: YIRANG IM, Yongin-si (KR); SEULONG KIM, Yongin-si (KR); YONGMIN KIM, Yongin-si (KR); YUNJEONG KIM, Yongin-si (KR); JIHEE PARK, Yongin-si (KR); GEUNHYUK JEONG, Yongin-si (KR)

(73) Assignee: Samsung Display Co., Ltd., Yongin-si (KR)

(21) Appl. No.: 18/675,348

(22) Filed: May 28, 2024

(30) Foreign Application Priority Data
Aug. 2, 2023 (KR) 10-2023-0101254

(51) Int. Cl. H10K 50/858; H10K 50/125; H10K 50/15; H10K 50/16; H10K 50/19; H10K 85/30; H10K 85/60

(52) U.S. Cl. CPC H10K 50/858; H10K 50/125; H10K 50/156; H10K 50/166; H10K 50/19; H10K 85/342; H10K 85/622; H10K 85/633; H10K 85/636; H10K 85/654; H10K 85/6572; H10K 85/6574; H10K 85/6576

(57) ABSTRACT

Embodiments provide a light emitting element that includes a first electrode, a first light emitting unit disposed on the first electrode, a charge generation unit disposed on the first light emitting unit, a second light emitting unit disposed on the charge generation unit, and a second electrode disposed on the second light emitting unit. The first light emitting unit includes a first hole transport region disposed on the first electrode, a first emission layer disposed on the first hole transport region, and a first electron transport region disposed on the first emission layer. The charge generation unit includes an n-type charge generation layer disposed on the first light emitting unit, and a p-type charge generation layer disposed on the n-type charge generation layer. At least one of the p-type charge generation layer and the first hole transport region each independently includes a tertiary amine compound including a cycloalkyl moiety.

### CROSS-REFERENCE TO RELATED APPLICATION(S)

This application claims priority to and benefits of Korean Patent Application No. 10-2023-0101254 under 35 U.S.C. § 119, filed on Aug. 2, 2023, in the Korean Intellectual Property Office, the entire contents of which are incorporated herein by reference.

### BACKGROUND

### 1. Technical Field

The disclosure relates to a light emitting element and a display device including the same.

### 2. Description of the Related Art

An organic light emitting element is a self-luminescent element that exhibits a rapid response time and is driven by a low voltage. Accordingly, an organic luminescence display device including an organic light emitting element may omit a separate light source and have various advantages including lower weight, thinner dimensions, excellent luminescence, and free of viewing angle dependence.

An organic light emitting element is a display element having an emission layer composed of an organic material between an anode and a cathode. Holes provided from the anode electrode and electrons provided from the cathode electrode recombine in an emission layer form excitons, and from the excitons, light corresponding to energy between the holes and electrons is produced.

A tandem organic light emitting element has a structure that includes two or more stacks of a hole transport layer/emission layer/electron transport layer structure between an anode and a cathode, and a charge generation layer assisting the generation and transfer of charges between the stacks.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having improved emission properties and element lifetime.

The disclosure also provides a display device having excellent display quality by including a light emitting element having improved emission efficiency and lifetime.

Embodiments provide a light emitting element which may include a first electrode, a first light emitting unit disposed on the first electrode, a charge generation unit disposed on the first light emitting unit, a second light emitting unit disposed on the charge generation unit, and a second electrode disposed on the second light emitting unit. The first light emitting unit may include a first hole transport region disposed on the first electrode, a first emission layer disposed on the first hole transport region, and a first electron transport region disposed on the first emission layer. The charge generation unit may include an n-type charge generation layer disposed on the first light emitting unit, and a p-type charge generation layer disposed on the n-type charge generation layer. At least one of the p-type charge generation layer and the first hole transport region may each independently include a tertiary amine compound including a cycloalkyl moiety, and a first refractive index of the p-type charge generation layer with respect to visible light may be greater than a second refractive index of the first hole transport region with respect to visible light.

In an embodiment, the first refractive index may be in a range of about 1.78 to about 2.0, and the second refractive index may be in a range of about 1.50 to about 1.78.

In an embodiment, a relation between the first refractive index and the second refractive index may be represented by Mathematical Equation 1.

$$0.001 \leq n 1 - n 2 \leq 0.2 \qquad [ Mathematical Equation 1 ]$$

In Mathematical Equation 1, n1 may be the first refractive index, and n2 may be the second refractive index.

In an embodiment, a first extinction coefficient of the p-type charge generation layer may be greater than a second extinction coefficient of the first hole transport region.

In an embodiment, a relation between the first extinction coefficient and the second extinction coefficient may be represented by Mathematical Equation 2.

$$0.0001 \leq k 1 - k 2 \leq 0.1 \qquad [ Mathematical Equation 2 ]$$

In Mathematical Equation 2, k1 may be the first extinction coefficient, and k2 may be the second extinction coefficient.

In an embodiment, the tertiary amine compound may be represented by Formula 1.

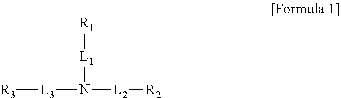

In Formula 1, L₁, L₂, and L₃ may each independently be a direct linkage, a substituted or unsubstituted arylene group of 6 to 30 ring-forming carbon atoms, a substituted or unsubstituted heteroarylene group of 2 to 30 ring-forming carbon atoms, or a substituted or unsubstituted cycloalkylene group of 5 to 30 ring-forming carbon atoms; R₁ may be a substituted or unsubstituted cycloalkyl group of 5 to 30 carbon atoms; R₂ may be a hydrogen atom, a deuterium atom, a halogen atom, a cyano group, a hydroxyl group, a silyl group, a substituted or unsubstituted alkyl group of 1 to 20 carbon atoms, a substituted or unsubstituted cycloalkyl group of 5 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms; and R₃ may be a group represented by Formula 2.

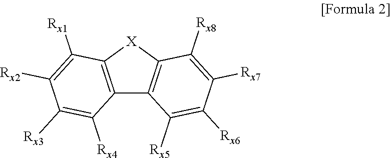

In Formula 2, X may be C(R_{y1})(R_{y2}), N(R_{y3}), O, or S; and Rₓ₁ to Rₓ₈ and R_{y1} to R_{y3} may each independently be a hydrogen atom, a deuterium atom, a halogen atom, a cyano group, a hydroxyl group, a substituted or unsubstituted alkyl group of 1 to 20 carbon atoms, a substituted or unsubstituted cycloalkyl group of 5 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, except that one of Rₓ₁ to Rₓ₈ is a position connected to Formula 1.

In an embodiment, R₁ may be a group represented by one of Formula 3-1 to Formula 3-5.

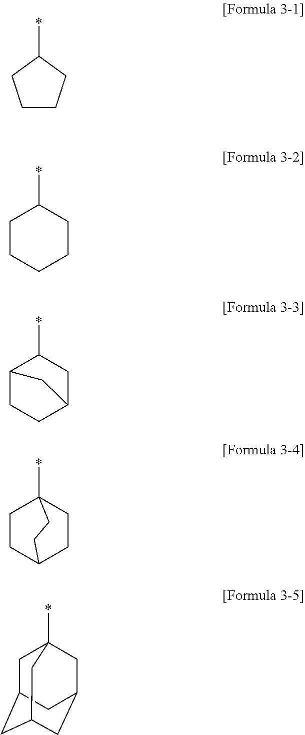

In Formula 3-1 to Formula 3-5,

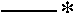 [SMILES: *C]

may be a position connected to L₁ in Formula 1, and at least one hydrogen atom may be optionally substituted with a deuterium atom.

In an embodiment, the first hole transport region may include the compound represented by Formula 1.

In an embodiment, the first hole transport region may include at least one compound selected from Compound Group 1, which is explained below.

In an embodiment, the first emission layer may include a first emission layer that overlaps a first light emitting region, a first green emission layer that overlaps a second light emitting region, and a first blue emission layer that overlaps a third light emitting region.

In an embodiment, the second light emitting unit may include a second emission layer disposed on the charge generation unit, and a second electron transport region disposed on the second emission layer.

In an embodiment, the second emission layer may include a second red emission layer that overlaps a first light emitting region, a second green emission layer that overlaps a second light emitting region, and a second blue emission layer that overlaps a third light emitting region.

Embodiments provide a display device which may include a base layer, a circuit layer disposed on the base layer, and a display device layer disposed on the circuit layer and including a light emitting element. The light emitting element may include a first electrode, a first light emitting unit disposed on the first electrode, a charge generation unit disposed on the first light emitting unit, a second light emitting unit disposed on the charge generation unit, and a second electrode disposed on the second light emitting unit. The first light emitting unit may include a first hole transport region disposed on the first electrode, a first emission layer disposed on the first hole transport region, and a first electron transport region disposed on the first emission layer. The charge generation unit may include an n-type charge generation layer disposed on the first light emitting unit, and a p-type charge generation layer disposed on the n-type charge generation layer. At least one of the p-type charge generation layer and the first hole transport region may include a tertiary amine compound including a cycloalkyl moiety, and a first refractive index of the p-type charge generation layer with respect to a visible light may be greater than a second refractive index of the first hole transport region with respect to visible light.

In an embodiment, the base layer may include a first light emitting region, a second light emitting region, and a third light emitting region, which are separated from each other in a plan view, and a peripheral region defined between the first to third light emitting regions. The display device layer may include a pixel definition layer that overlaps the peripheral region and defining opening parts therein; the opening parts may overlap each of the first to third light emitting regions; and the first emission layer may be disposed in the opening parts.

In an embodiment, the first emission layer may include a first red emission layer that overlaps the first light emitting region, a first green emission layer that overlaps the second light emitting region, and a first blue emission layer that overlaps the third light emitting region.

In an embodiment, the light emitting element may include a first light emitting element including the first red emission layer and emitting red light, a second light emitting element including the first green emission layer and emitting green light, and a third light emitting element including the first blue emission layer and emitting blue light.

In an embodiment, refractive indexes of the p-type charge generation layer with respect to the red light, the green light and the blue light may be respectively greater than refractive indexes of the first hole transport region with respect to the red light, the green light, and the blue light.

In an embodiment, extinction coefficients of the p-type charge generation layer with respect to the red light, the green light and the blue light may be respectively greater than extinction coefficients of the first hole transport region with respect to the red light, the green light, and the blue light.

In an embodiment, the first electrode, the first hole transport region, the first electron transport region, and the second electrode may be provided as common layers in each of the first light emitting region, the second light emitting region, and the third light emitting region.

In an embodiment, the n-type charge generation layer and the p-type charge generation layer may be provided as common layers in each of the first light emitting region, the second light emitting region, and the third light emitting region.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIG. 3A to FIG. 3E are each a schematic cross-sectional view of a light emitting element according to an embodiment;

FIG. 4 is a schematic cross-sectional view of a light emitting element according to an embodiment; and

FIG. 5 is a schematic diagram showing a vehicle in which a display device is disposed according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the description, the term “substituted or unsubstituted” may describe a group that is substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may be substituted or unsubstituted. For example, a biphenyl group may be interpreted as an aryl group or it may be interpreted as a phenyl group substituted with a phenyl group.

In the description, the term “forming a ring via the combination with an adjacent group” may be interpreted as forming a substituted or unsubstituted hydrocarbon ring, or a substituted or unsubstituted heterocycle via the combination with an adjacent group. The hydrocarbon ring may be aliphatic or aromatic. The heterocycle may be an aliphatic or aromatic. The hydrocarbon ring and the heterocycle may each independently be monocyclic or polycyclic. A ring that is formed via the combination with an adjacent group may itself be combined with another ring to form a spiro structure.

In the description, the term “adjacent group” may be interpreted as a substituent that is substituted for an atom which is directly combined with an atom substituted with a corresponding substituent, as another substituent that is substituted for an atom which is substituted with a corresponding substituent, or as a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. For example, in 4,5-dimethylphenanthrene, two methyl groups may be interpreted as “adjacent groups” to each other.

In the description, examples of a halogen atom may include a fluorine atom, a chlorine atom, a bromine atom, or an iodine atom.

In the description, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, an 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, a 3-methylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., without limitation.

In the description, a cycloalkyl group may be a ring-type alkyl group. The number of carbon atoms in the cycloalkyl group may be 3 to 50, 3 to 30, or 3 to 20, 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., without limitation.

In the description, an alkenyl group may be a hydrocarbon group that includes one or more carbon-carbon double bonds in the middle or at a terminus of an alkyl group having 2 or more carbon atoms. An alkenyl group may be a linear or branched. The number of carbon atoms is not particularly limited, but may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styrylvinyl group, etc., without limitation.

In the description, an alkynyl group may be a hydrocarbon group that includes one or more carbon-carbon triple bonds in the middle or at a terminus of an alkyl group having 2 or more carbon atoms. The alkynyl group may be a linear chain or a branched chain. The number of carbon atoms in an alkynyl group is not specifically limited, but may be 2 to 30, 2 to 20, or 2 to 10. Examples of an alkynyl group may include an ethynyl group, a propynyl group, etc., without limitation.

In the description, a hydrocarbon ring group may be an optional functional group or substituent derived from an aliphatic hydrocarbon ring. For example, a hydrocarbon ring group may be a saturated hydrocarbon ring group of 5 to 20 ring-forming carbon atoms.

In the description, an aryl group may be optional functional group or substituent derived from an aromatic hydrocarbon ring. An aryl group may be monocyclic or polycyclic. The number of carbon atoms for forming rings in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., without limitation.

In the description, a fluorenyl group may be substituted, and two substituents may be combined with each other to form a spiro structure. Examples of a substituted fluorenyl group may include the groups shown below, but embodiments are not limited thereto.

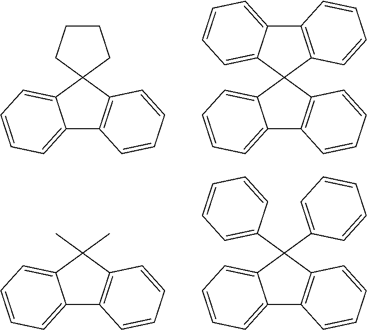

In the description, a heterocyclic group may be an optional functional group or substituent derived from a ring that includes one or more of B, O, N, P, Si, S, Se, and Te as heteroatoms. A heterocyclic group may be aliphatic or aromatic. An aromatic heterocyclic group may be a heteroaryl group. An aliphatic heterocyclic group and an aromatic heterocyclic group may each independently be monocycle or polycycle.

In the description, a heterocyclic group may include one or more of B, O, N, P, Si, S, Se, and Te as heteroatoms. If a heterocyclic group includes two or more heteroatoms, two or more heteroatoms may be the same or different from each other. A heterocyclic group may be monocyclic or polycyclic, and a heterocyclic group may be a heteroaryl group. The ring-forming carbon of a heterocyclic group may be 2 to 30, 2 to 20, or 2 to 10.

In the description, an aliphatic heterocyclic group may include one or more among B, O, N, P, Si, and S as heteroatoms. The number of ring-forming carbon atoms of an aliphatic heterocyclic group may be 2 to 30, 2 to 20, or 2 to 10. Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., without limitation.

In the description, a heteroaryl group may include one or more of B, O, N, P, Si, and S as heteroatoms. If the heteroaryl group includes two or more heteroatoms, two or more heteroatoms may be the same or different from each other. A heteroaryl group may be monocyclic or polycyclic. The number of carbon atoms for forming rings of a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, a N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., without limitation.

In the description, the above description of an aryl group may be applied to an arylene group except that an arylene group is a divalent group. The above description of a heteroaryl group may be applied to a heteroarylene group except that a heteroarylene group is a divalent group.

In the description, a silyl group may be an alkyl silyl group and an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the description, the number of carbon atoms in a carbonyl group is not particularly limited, but may be 1 to 40, 1 to 30, or 1 to 20. For example, a carbonyl group may have one of the structures below, but embodiments are not limited thereto.

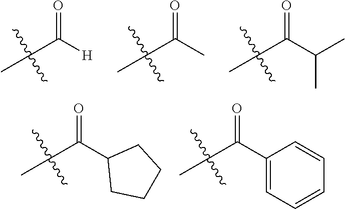

In the description, the carbon number in a sulfinyl group or in a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the description, a thio group may be an alkyl thio group or an aryl thio group. A thio group may be an alkyl group or an aryl group combined with a sulfur atom. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the description, an oxy group may be an alkyl group or an aryl group that is combined with an oxygen atom. An oxy group may be an alkoxy group or an aryl oxy group. An alkoxy group may be linear, branched, or cyclic. The number of carbon atoms in an alkoxy group is not particularly limited but may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc. However, embodiments are not limited thereto.

In the description, a boron group may be an alkyl group or an aryl group combined with a boron atom. A boron group may be an alkyl boron group or an aryl boron group. Examples of a boron group may include a dimethylboron group, a diethylboron group, a t-butylmethylboron group, a diphenylboron group, a phenylboron group, etc., without limitation.

In the description, the number of carbon atoms in an amine group is not particularly limited, but may be 1 to 30. An amine group may be an alkyl amine group or an aryl amine group. Examples of an amine group include a methylamine group, a dimethylamine group, a phenylamine group, a diphenylamine group, a naphthylamine group, a 9-methyl-anthracenylamine group, etc., without limitation.

In the description, alkyl groups within an alkylthio group, an alkylsulfoxy group, an alkylaryl group, an alkyl boron group, an alkyl silyl group, or an alkyl amine group may be the same as an example of the above-described alkyl group.

In the description, aryl groups in an aryloxy group, arylthio group, an arylsulfoxy group, an arylboron group, an aryl silyl group, or an aryl amine group may be the same as an example of the above-described aryl group.

In the description, a direct linkage may be a single bond.

In the description, the symbols

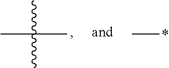

each represent a bond to a neighboring atom in a corresponding formula or moiety.

Hereinafter, embodiments will be explained with reference to the drawings.

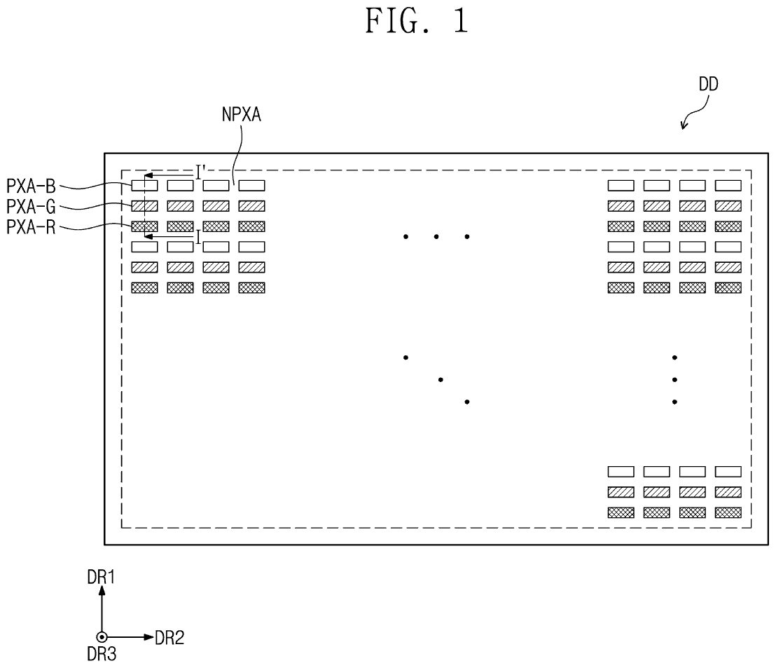

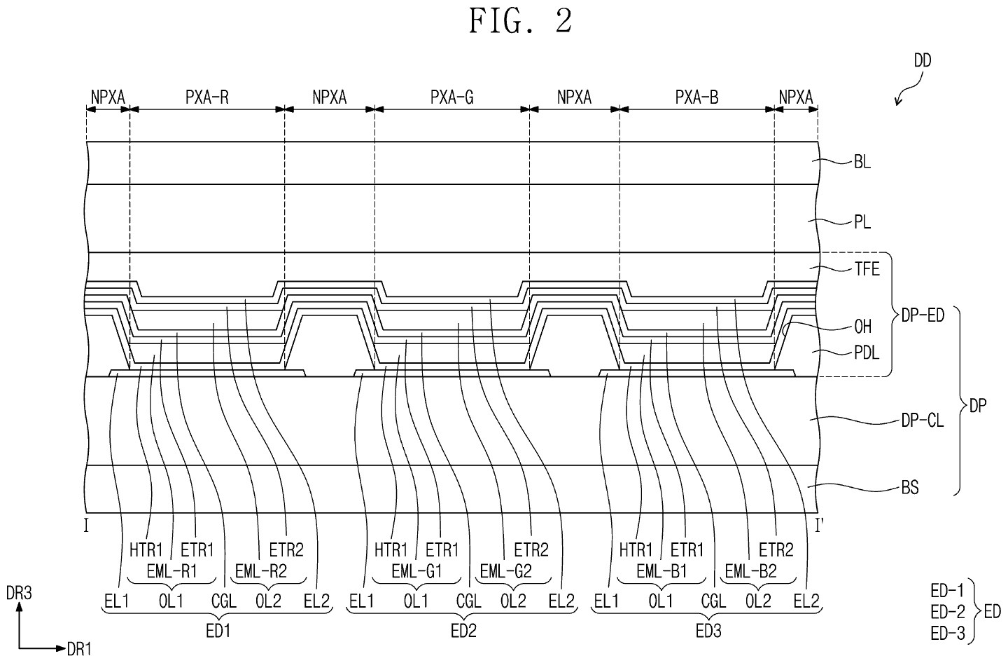

FIG. 1 is a schematic plan view of a display device DD according to an embodiment. FIG. 2 is a schematic cross-sectional view of a display device DD according to an embodiment. FIG. 2 is a schematic cross-sectional view showing a part taken along to line I-I′ of FIG. 1.

The display device DD may include a display panel DP and an optical layer PL disposed on the display panel DP. The display panel DP may include light emitting elements ED-1, ED-2, and ED-3. The display device DD may include multiples of each of the light emitting elements ED-1, ED-2, and ED-3. The optical layer PL may be disposed on the display panel DP to control light that is reflected at the display panel DP from an external light. The optical layer PL may include, for example, a polarization layer or a color filter layer. Although not shown in the drawings, in an embodiment, the optical layer PL may be omitted in the display device DD.

On the optical layer PL, a base substrate BL may be disposed. The base substrate BL may provide a base surface where the optical layer PL is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, the base substrate BL may be omitted according to an embodiment.

The display device DD according to an embodiment may further include a plugging layer (not shown). The plugging layer (not shown) may be disposed between a display device layer DP-ED and a base substrate BL. The plugging layer (not shown) may be an organic layer. The plugging layer (not shown) may include at least one of an acrylic resin, a silicon-based resin, and an epoxy-based resin.

The display panel DP may include a base layer BS, a circuit layer DP-CL provided on the base layer BS and a display device layer DP-ED. The display device layer DP-ED may include a pixel definition layer PDL, light emitting elements ED-1, ED-2, and ED-3 disposed between portions of the pixel definition layer PDL, and an encapsulating layer TFE disposed on the light emitting elements ED-1, ED-2, and ED-3.

The base layer BS may provide a base surface where the display device layer DP-ED is disposed. The base layer BS may be a glass substrate, a metal substrate, a plastic substrate, etc. However, embodiments are not limited thereto, and the base layer BS may be an inorganic layer, an organic layer, or a composite material layer.

In an embodiment, the circuit layer DP-CL is disposed on the base layer BS, and the circuit layer DP-CL may include multiple transistors (not shown). The transistors (not shown) may each include a control electrode, an input electrode, and an output electrode. For example, the circuit layer DP-CL may include switching transistors and driving transistors for driving the light emitting elements ED-1, ED-2, and ED-3 of the display device layer DP-ED.

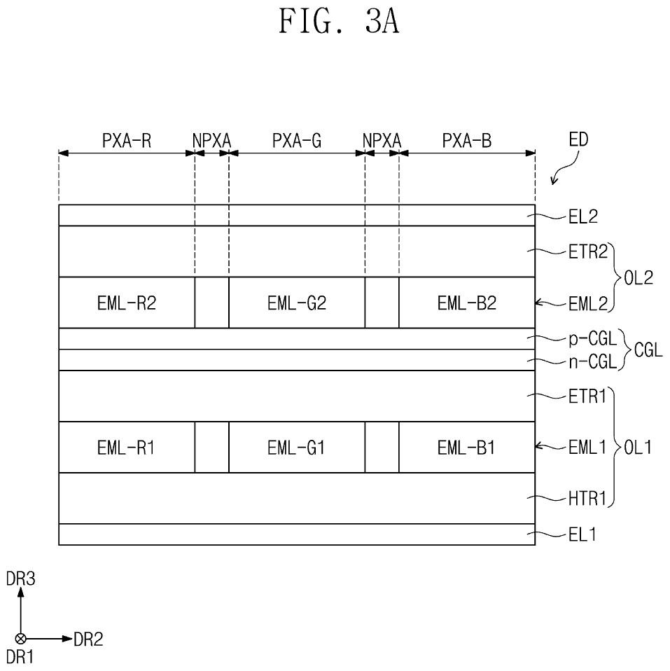

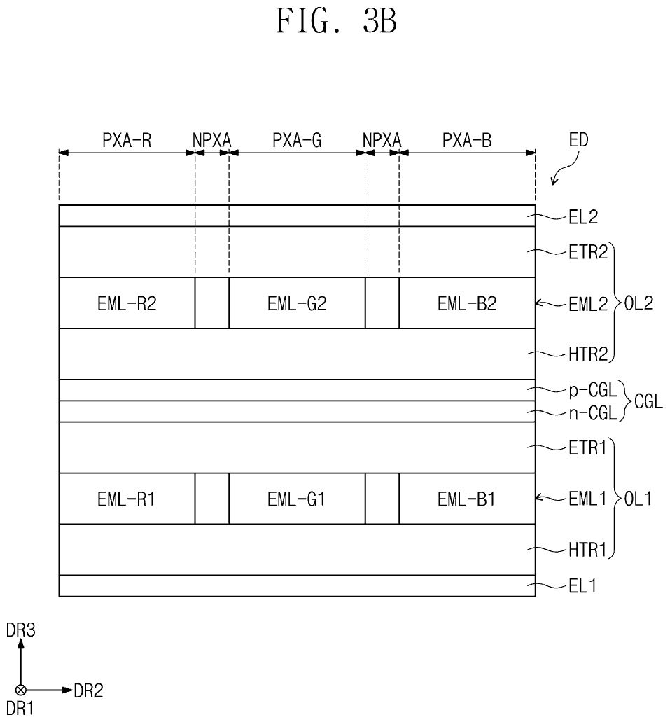

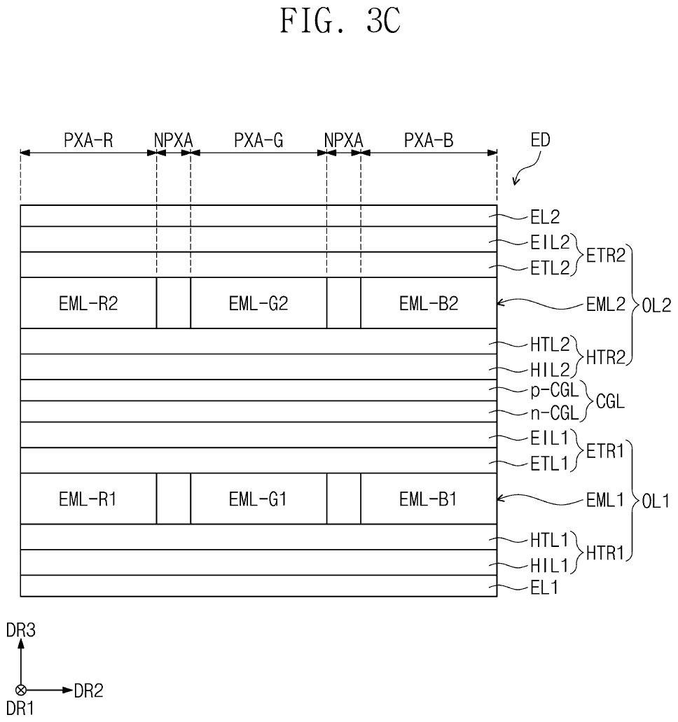

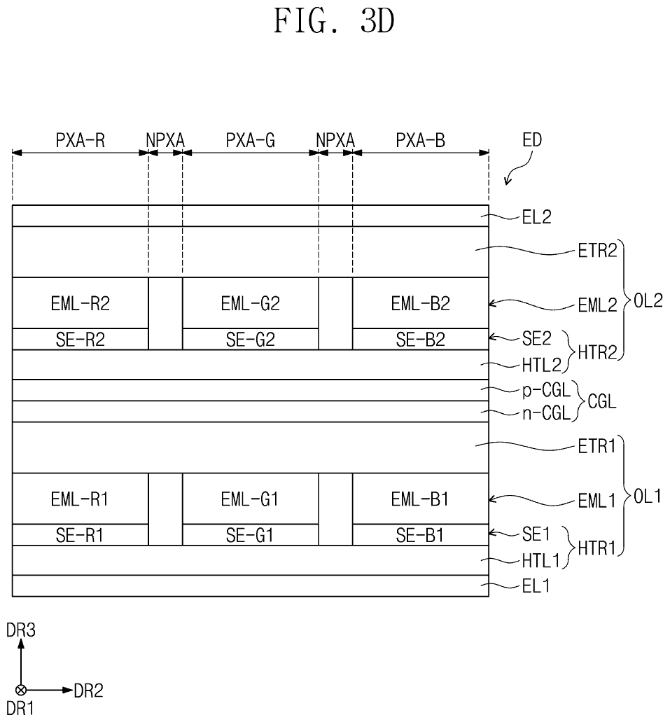

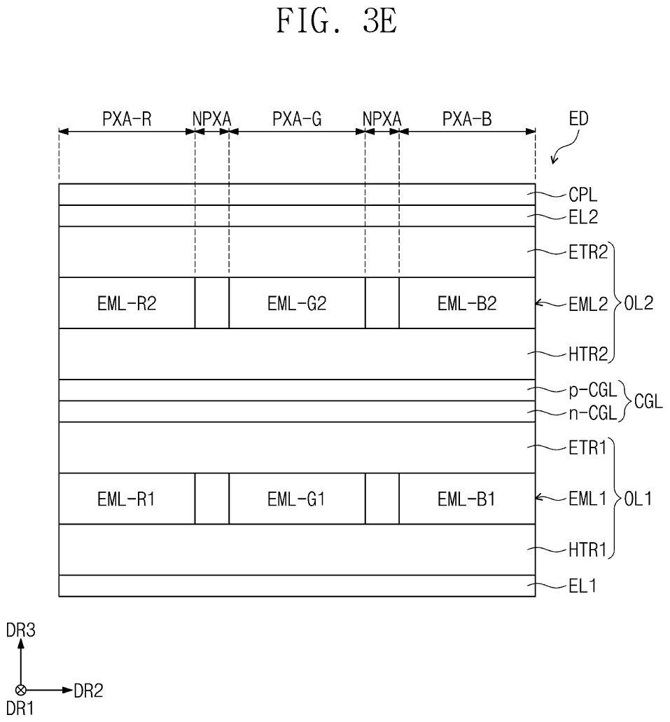

Light emitting elements ED-1, ED-2, and ED-3 may include a first light emitting element ED-1, a second light emitting element ED-2, and a third light emitting element ED-3. The light emitting elements ED-1, ED-2, and ED-3 may each have a structure of a light emitting element ED according to any one of FIG. 3A to FIG. 3E, which will be explained later. The light emitting elements ED-1, ED-2, and ED-3 may each include a first light emitting unit OL1, a charge generation unit CGL, a second light emitting unit OL2, and a second electrode EL2. The light emitting elements ED-1, ED-2, and ED-3 may each be a light emitting element of a tandem structure. In each of the light emitting elements ED-1, ED-2, and ED-3, two light emitting units may emit light in a same wavelength region.

The first light emitting unit OL1 may include a first hole transport region HTR1, first emission layers EML-R1, EML-G1, and EML-B1, and a first electron transport region ETR1. The second light emitting unit OL2 may include second emission layers EML-R2, EML-G2, and EML-B2, and a second electron transport region ETR2. FIG. 2 illustrates an embodiment in which the first and second emission layers EML-R1, EML-G1, EML-B1, EML-R2, EML-G2, and EML-B2 of the light emitting elements ED-1, ED-2, and ED-3 are disposed in the opening parts OH defined in the pixel definition layer PDL, and the first hole transport region HTR1, the first and second electron transport regions ETR1 and ETR2, the charge generation unit CGL and the second electrode EL2 are each provided as common layers for the light emitting elements ED-1, ED-2, and ED-3. However, embodiments are not limited thereto. Although not illustrated in FIG. 2, in an embodiment, at least a portion of the first hole transport region HTR1, the first and second electron transport regions ETR1 and ETR2, and the charge generation unit CGL may each be patterned in the opening parts OH defined in the pixel definition layer PDL and provided as pattern layers. In the description, a “common layer” may be commonly provided over all of the light emitting elements ED-1, ED-2, and ED-3 to substantially form one element, and a “pattern layer” may be patterned and separately provided in the opening parts OH defined in the pixel definition layer PDL. For example, in an embodiment, the first hole transport region HTR1, the first and second emission layers EML-R1, EML-G1, EML-B1, EML-R2, EML-G2, and EML-B2, the charge generation unit CGL and the first and second electron transport regions ETR1 and ETR2 of the light emitting elements ED-1, ED-2, and ED-3 may each be provided by being patterned by an ink jet printing method.

An encapsulating layer TFE may cover the light emitting elements ED-1, ED-2, and ED-3. The encapsulating layer TFE may encapsulate the display device layer DP-ED. The encapsulating layer TFE may be a thin film encapsulating layer. The encapsulating layer TFE may be a single layer or a stack of multiple layers. The encapsulating layer TFE may include at least one insulating layer. The encapsulating layer TFE according to an embodiment may include at least one inorganic layer (hereinafter, encapsulating inorganic layer). In an embodiment, the encapsulating layer TFE may include at least one organic layer (hereinafter, encapsulating organic layer) and at least one encapsulating inorganic layer.

The encapsulating inorganic layer may protect the display device layer DP-ED from moisture and/or oxygen, and the encapsulating organic layer may protect the display device layer DP-ED from foreign materials such as dust particles. The encapsulating inorganic layer may include silicon nitride, silicon oxy nitride, silicon oxide, titanium oxide, or aluminum oxide, without limitation. The encapsulating organic layer may include an acrylic compound, an epoxy-based compound, etc. The encapsulating organic layer may include a photopolymerizable organic material, without limitation.

The encapsulating layer TFE may be disposed on the second electrode EL2 and may be disposed to fill the opening parts OH.

Referring to FIG. 1 and FIG. 2, the display device DD may include a non-light emitting region NPXA and light emitting regions PXA-R, PXA-G and PXA-B. The light emitting regions PXA-R, PXA-G, and PXA-B may each be a region that emits light respectively produced from the light emitting elements ED-1, ED-2, and ED-3. The light emitting regions PXA-R, PXA-G, and PXA-B may each be separated from each other in a plan view.

The light emitting regions PXA-R, PXA-G and PXA-B may each be regions that are separated from each other by the pixel definition layer PDL. The non-light emitting regions NPXA may be regions between neighboring light emitting regions PXA-R, PXA-G and PXA-B and may be regions corresponding to the pixel definition layer PDL. In an embodiment, each of the light emitting regions PXA-R, PXA-G and PXA-B may each correspond to a pixel. The pixel definition layer PDL may separate the light emitting elements ED-1, ED-2, and ED-3. The first emission layers EML-R1, EML-G1, and EML-B1 and the second emission layers EML-R2, EML-G2, and EML-B2 of the light emitting elements ED-1, ED-2, and ED-3 may be disposed and separated from each other in the opening parts OH defined in the pixel definition layer PDL.

The light emitting regions PXA-R, PXA-G and PXA-B may be arranged into multiple groups according to the color of light produced from the light emitting elements ED-1, ED-2, and ED-3. In the display device DD according to an embodiment shown in FIG. 1 and FIG. 2, three light emitting regions PXA-R, PXA-G, and PXA-B emitting red light, green light and blue light are illustrated as an example. For example, the display device DD may include a first light emitting region of a red light emitting region PXA-R, a second light emitting region of a green light emitting region PXA-G and a third light emitting region of a blue light emitting region PXA-B, which are distinct from each other.

In the display device DD according to an embodiment, the light emitting elements ED-1, ED-2, and ED-3 may emit light having different wavelength regions. For example, in an embodiment, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments not limited thereto, and the first to third light emitting elements ED-1, ED-2, and ED-3 may emit light in a same wavelength region, or at least one thereof may emit light in a different wavelength region.

The light emitting regions PXA-R, PXA-G, and PXA-B in the display device DD according to an embodiment may be arranged in a stripe configuration. Referring to FIG. 1, multiple red light emitting regions PXA-R, multiple green light emitting regions PXA-G, and multiple blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

In FIG. 1 and FIG. 2, the areas of the light emitting regions PXA-R, PXA-G, and PXA-B are shown to all have a similar area, but embodiments are not limited thereto. In an embodiment, the areas of the light emitting regions PXA-R, PXA-G, and PXA-B may be different in size or shape from each other according to a wavelength region of light emitted. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration shown in FIG. 1, and the arrangement order of the red light emitting regions PXA-R, the green light emitting regions PXA-G, and the blue light emitting regions PXA-B may be provided in various combinations according to the display quality properties that are required for the display device DD. For example, the light emitting regions PXA-R, PXA-G, and PXA-B may be arranged in a pentile configuration (such as PENTILE®) or in a diamond configuration (such as Diamond Pixel®).

The areas of the light emitting regions PXA-R, PXA-G, and PXA-B may be different in size from each other. For example, in an embodiment, an area of the green light emitting region PXA-G may be smaller than an area of the blue light emitting region PXA-B, but embodiments are not limited thereto.

FIG. 3A to FIG. 3E are each a schematic cross-sectional view of a light emitting element according to an embodiment.

Referring to FIG. 3A, the light emitting element ED according to an embodiment may include a first electrode EL1, a first light emitting unit OL1, a charge generation unit CGL, a second light emitting unit OL2, and a second electrode EL2. In an embodiment, the light emitting element ED, the first light emitting unit OL1 may include a first hole transport region HTR1, a first emission layer EML1, and a first electron transport region ETR1, and the second light emitting unit OL2 may include a second emission layer EML2, and a second electron transport region ETR2.

In comparison to FIG. 3A, FIG. 3B is a schematic cross-sectional view of a light emitting element ED in which the second light emitting unit OL2 further includes a second hole transport region HTR2 disposed under the second emission layer EML2. In comparison to FIG. 3B, FIG. 3C is a schematic cross-sectional view of a light emitting element ED in which the first and second hole transport regions HTR1 and HTR2 include first and second hole injection layers HIL1 and HIL2, and first and second hole transport layers HTL1 and HTL2, respectively, and the first and second electron transport regions ETR1 and ETR2 include first and second electron injection layers EIL1 and EIL2, and first and second electron transport layers ETL1 and ETL2, respectively. In comparison to FIG. 3B, FIG. 3D is a schematic cross-sectional view of a light emitting element ED in which the first hole transport region HTR1 includes first emission auxiliary layers SE-R1, SE-G1, and SE-B1, and a first and hole transport layer HTL1, and the second hole transport region HTR2 includes second emission auxiliary layers SE-R2, SE-G2, and SE-B2, and a second hole transport layer HTL2. In comparison to FIG. 3B, FIG. 3E is a schematic cross-sectional view of a light emitting element ED that further includes a capping layer CPL disposed on the second electrode EL2.

Hereinafter, the constituent elements included in each of the light emitting elements ED will be explained referring to FIG. 3A to FIG. 3E.

The first electrode EL1 may have conductivity. The first electrode EL1 may be formed using a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, or oxides thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), and indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). In another embodiment, the first electrode EL1 may have a multilayer structure including a reflective layer or a transflective layer formed of the above-described materials, and a transmissive conductive layer formed of ITO, IZO, ZnO, or ITZO. For example, the first electrode EL1 may have a three-layer structure of ITO/Ag/ITO. However, an embodiments are not limited thereto. In an embodiment first electrode EL1 may include the above-described metal materials, combinations of two or more metal materials of the above-described metal materials, or oxides of the above-described metal materials. A thickness of the first electrode EL1 may be in a range of about 700 Å to about 10,000 Å. For example, the thickness of the first electrode EL1 may be in a range of about 1,000 Å to about 3,000 Å.

The first light emitting unit OL1 may be provided on the first electrode EL1. The first light emitting unit OL1 may include a first hole transport region HTR1, a first emission layer EML1 and a first electron transport region ETR1.

The first hole transport region HTR1 of the first light emitting unit OL1 may be provided on the first electrode EL1. The first hole transport region HTR1 may include at least one of a first hole injection layer HIL1, a first hole transport layer HTL1, a first emission auxiliary layer SE1, and a first electron blocking layer (not shown). A thickness of the hole transport region HTR may be, for example, in a range of about 50 Å to about 15,000 Å.

The first hole transport region HTR1 may be a layer consisting of a single material, a layer including different materials, or a structure including multiple layers including different materials.

In embodiments, the first hole transport region HTR1 may have a single layer structure of a first hole injection layer HIL1 or a first hole transport layer HTL1, or may have a single layer structure formed of a hole injection material and a hole transport material. In embodiments, the first hole transport region HTR1 may have a single layer structure formed of different materials, or may have a structure stacked from the first electrode EL1 of a first hole injection layer HIL1/first hole transport layer HTL1, a first hole injection layer HIL1/first hole transport layer HTL1/first emission auxiliary layer SE1, or a first hole injection layer HIL1/first hole transport layer HTL1/first electron blocking layer (not shown), without limitation. If the first transport region HTR1 includes the first emission auxiliary layer SE1, the first emission auxiliary layer SE1 may be a pattern layer patterned and provided in an opening part OH (see FIG. 2). For example, the first emission auxiliary layer SE1 may include a first red emission auxiliary layer SE-R1 that overlaps the first light emitting region PXA-R, a first green emission auxiliary layer SE-G1 that overlaps the second light emitting region PXA-G, and a first blue emission auxiliary layer SE-B1 that overlaps the third light emitting region PXA-B. The first emission auxiliary layer SE1 may compensate for a resonance distance according to a wavelength of light emitted from the first emission layer EML1 and may control hole charge balance to increase light emission efficiency. In an embodiment, the first emission auxiliary layer SE1 may prevent electron injection to the first hole transport region HTR1.

The first hole transport region HTR1 may be formed using various methods such as a vacuum deposition method, a spin coating method, a cast method, a Langmuir-Blodgett (LB) method, an inkjet printing method, a laser printing method, and a laser induced thermal imaging (LITI) method.

The first hole transport region HTR1 may include a tertiary amine compound including a cycloalkyl moiety. In an embodiment, the first hole transport region HTR1 may include a host and a p-dopant material dispersed in the host, and the first hole transport region HTR1 may include the tertiary amine compound including a cycloalkyl moiety as the host. In an embodiment, the tertiary amine compound including the cycloalkyl moiety will be explained later, and may be referred to as a first compound. The first compound according to an embodiment may have a structure of an amine compound introducing a substituent of a cycloalkyl group, and may show improved emission properties and element lifetime characteristics.

The first compound according to an embodiment may be represented by Formula 1.

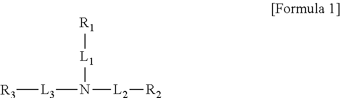

In Formula 1, L₁, L₂, and L₃ may each independently be a direct linkage, a substituted or unsubstituted arylene group of 6 to 30 ring-forming carbon atoms, a substituted or unsubstituted heteroarylene group of 2 to 30 ring-forming carbon atoms, or a substituted or unsubstituted cycloalkylene group of 5 to 30 ring-forming carbon atoms. For example, L₁ may be a direct linkage, an unsubstituted phenylene group, an unsubstituted naphthylene group, an unsubstituted divalent biphenyl group, or an unsubstituted divalent N-arylcarbazole group; and L₂ may be a direct linkage, an unsubstituted phenylene group, an unsubstituted naphthylene group, or an unsubstituted divalent biphenyl group.

In Formula 1, R₁ may be a substituted or unsubstituted cycloalkyl group of 5 to 30 carbon atoms. For example, R₁ may be an unsubstituted cycloalkyl group of 5 to 10 carbon atoms. For example, R₁ may be a substituted or unsubstituted cyclopentyl group, a substituted or unsubstituted cyclohexyl group, a substituted or unsubstituted cyclooctyl group, or a substituted or unsubstituted adamantyl group.

In Formula 1, R₂ may be a hydrogen atom, a deuterium atom, a halogen atom, a cyano group, a hydroxyl group, a silyl group, a substituted or unsubstituted alkyl group of 1 to 20 carbon atoms, a substituted or unsubstituted cycloalkyl group of 5 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms. For example, R₂ may be an unsubstituted phenyl group, an unsubstituted N-arylcarbazole group, or an unsubstituted fluorenyl group.

In Formula 1, R₃ may be a group represented by Formula 2.

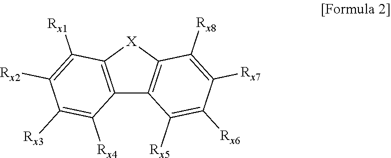

In Formula 2, X may be C(R_{y1})(R_{y2}), N(R_{y3}), O, or S.

In Formula 2, R_{y1} to R_{y3} may each independently be a hydrogen atom, a deuterium atom, a halogen atom, a cyano group, a hydroxyl group, a substituted or unsubstituted alkyl group of 1 to 20 carbon atoms, a substituted or unsubstituted cycloalkyl group of 5 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. For example, X may be C(R_{y1})(R_{y2}), and R_{y1} and R_{y2} may each independently be an unsubstituted methyl group, and the substituent represented by Formula 2 may provide a fluorenyl moiety. In another embodiment, X may be N(R_{y3}), and R_{y2} may be an unsubstituted phenyl group, and the substituent represented by Formula 2 may provide an N-arylcarbazole moiety.

In Formula 2, Rₓ₁ to Rₓ₈ may each independently be a hydrogen atom, a deuterium atom, a halogen atom, a cyano group, a hydroxyl group, a substituted or unsubstituted alkyl group of 1 to 20 carbon atoms, a substituted or unsubstituted cycloalkyl group of 5 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, except that one of Rₓ₁ to Rₓ₈ may be a position connected to Formula 1. For example, Rₓ₁ to Rₓ₆ and Rₓ₈ may each independently be a hydrogen atom or a deuterium atom, and Rₓ₇ may be a position connected to Formula 1.

In an embodiment, in Formula 1, R₁ may be a group represented by one of Formula 3-1 to Formula 3-5.

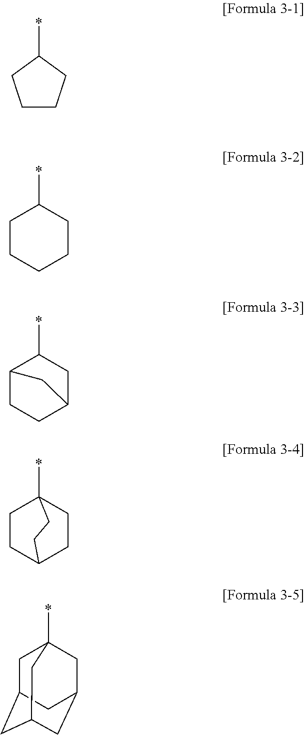

In Formula 3-1 to Formula 3-5,

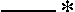 [SMILES: *C]

may be a position connected to L₁ in Formula 1; and at least one hydrogen atom may be optionally substituted with a deuterium atom.

In an embodiment, the first compound may be any compound selected from Compound Group 1. In an embodiment, in the light emitting element ED, at least one of a first hole transport region HTR1 and a p-type charge generation layer p-CGL may each independently include at least one first compound selected from Compound Group 1.

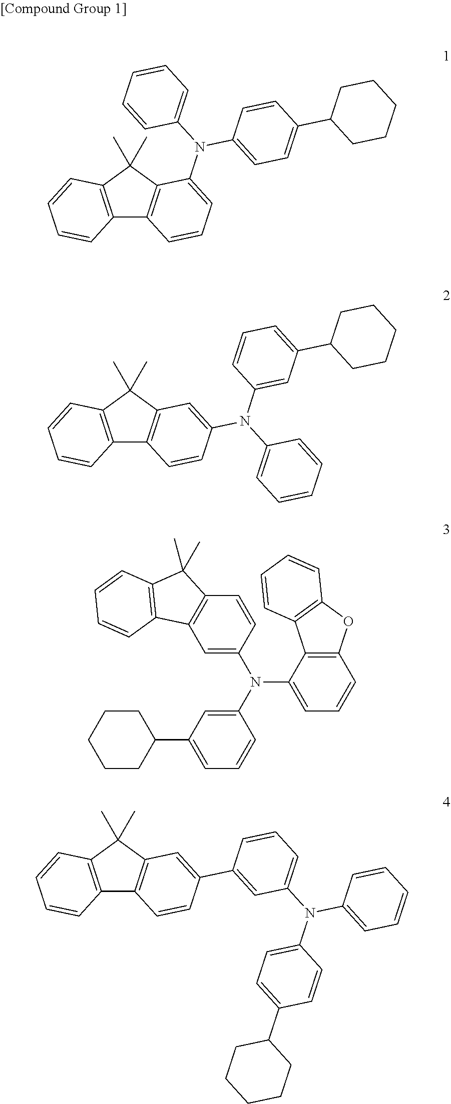

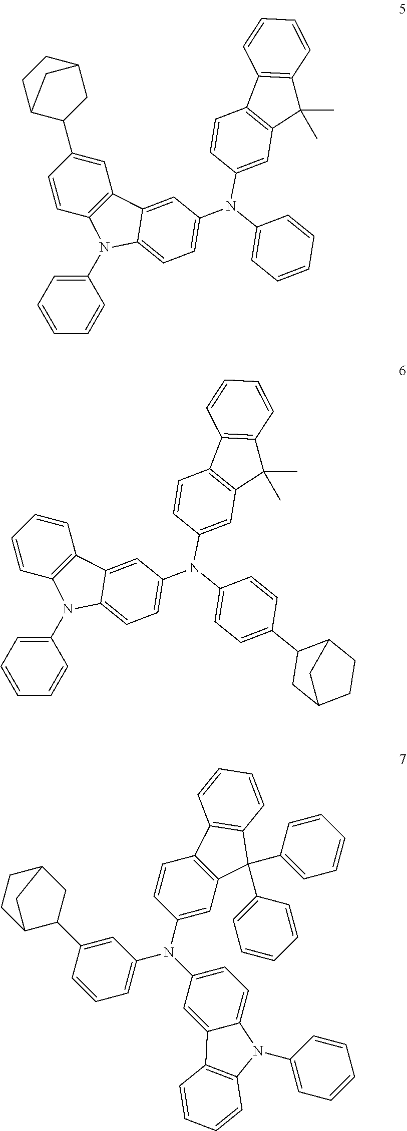 [SMILES: CC1(C)c2ccccc2-c2ccc(N(c3ccccc3)c3ccc4c(c3)c3cc(C5CC6CCC5C6)ccc3n4-c3ccccc3)cc21 ; CC1(C)c2ccccc2-c2ccc(N(c3ccc(C4CC5CCC4C5)cc3)c3ccc4c(c3)c3ccccc3n4-c3ccccc3)cc21 ; c1ccc(-n2c3ccccc3c3cc(N(c4cccc(C5CC6CCC5C6)c4)c4ccc5c(c4)C(c4ccccc4)(c4ccccc4)c4ccccc4-5)ccc32)cc1]

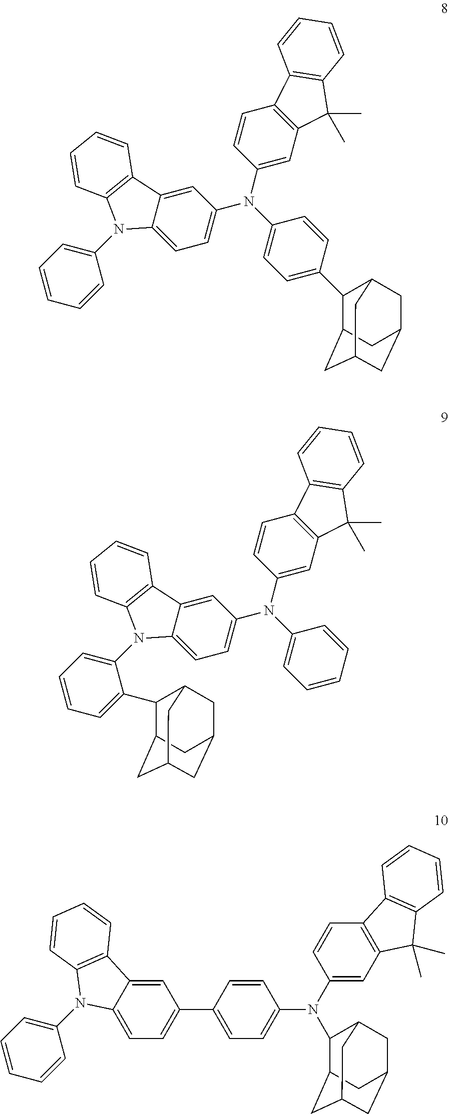 [SMILES: CC1(C)c2ccccc2-c2ccc(N(c3ccc(C4C5CC6CC(C5)CC4C6)cc3)c3ccc4c(c3)c3ccccc3n4-c3ccccc3)cc21 ; CC1(C)c2ccccc2-c2ccc(N(c3ccccc3)c3ccc4c(c3)c3ccccc3n4-c3ccccc3C3C4CC5CC(C4)CC3C5)cc21 ; CC1(C)c2ccccc2-c2ccc(N(c3ccc(-c4ccc5c(c4)c4ccccc4n5-c4ccccc4)cc3)C3C4CC5CC(C4)CC3C5)cc21]

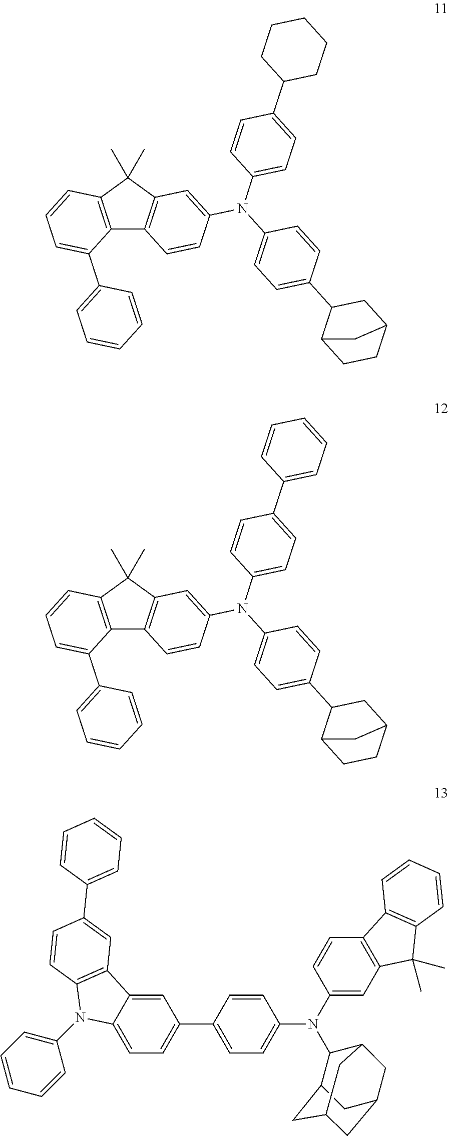 [SMILES: CC1(C)c2cc(N(c3ccc(C4CCCCC4)cc3)c3ccc(C4CC5CCC4C5)cc3)ccc2-c2c(-c3ccccc3)cccc21 ; CC1(C)c2cc(N(c3ccc(-c4ccccc4)cc3)c3ccc(C4CC5CCC4C5)cc3)ccc2-c2c(-c3ccccc3)cccc21 ; CC1(C)c2ccccc2-c2ccc(N(c3ccc(-c4ccc5c(c4)c4cc(-c6ccccc6)ccc4n5-c4ccccc4)cc3)C3C4CC5CC(C4)CC3C5)cc21]

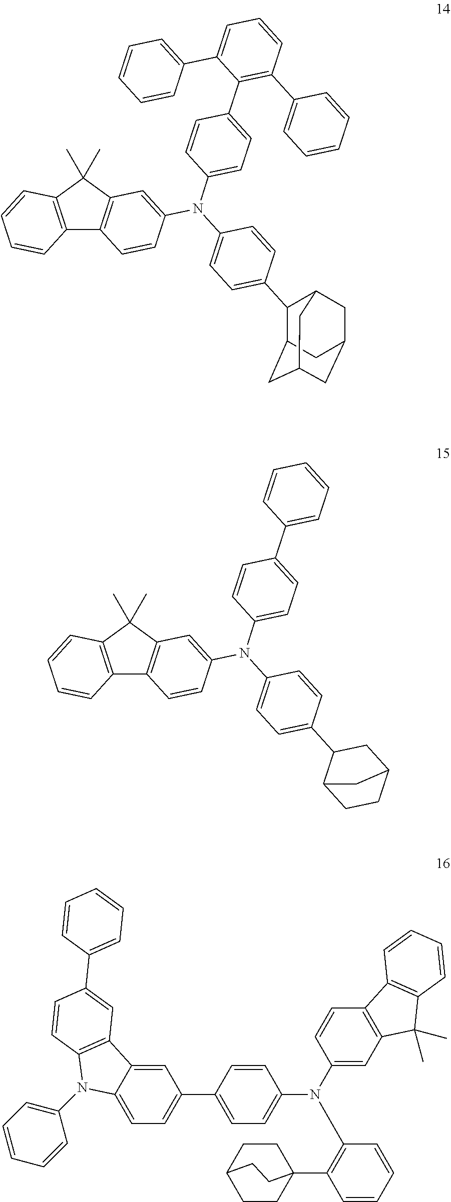 [SMILES: CC1(C)c2ccccc2-c2ccc(N(c3ccc(-c4c(-c5ccccc5)cccc4-c4ccccc4)cc3)c3ccc(C4C5CC6CC(C5)CC4C6)cc3)cc21 ; CC1(C)c2ccccc2-c2ccc(N(c3ccc(-c4ccccc4)cc3)c3ccc(C4CC5CCC4C5)cc3)cc21 ; CC1(C)c2ccccc2-c2ccc(N(c3ccc(-c4ccc5c(c4)c4cc(-c6ccccc6)ccc4n5-c4ccccc4)cc3)c3ccccc3C34CCC(CC3)CC4)cc21]

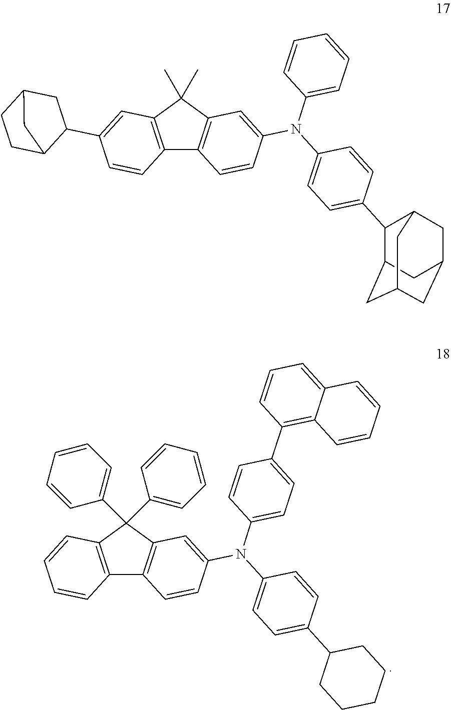 [SMILES: CC1(C)c2cc(C3CC4CCC3C4)ccc2-c2ccc(N(c3ccccc3)c3ccc(C4C5CC6CC(C5)CC4C6)cc3)cc21 ; c1ccc(C2(c3ccccc3)c3ccccc3-c3ccc(N(c4ccc(-c5cccc6ccccc56)cc4)c4ccc(C5CCCCC5)cc4)cc32)cc1]

In an embodiment, the first hole transport region HTR1 may include multiple compounds. For example, the first hole transport region HTR1 may include the first compound represented by Formula 1 and may further include a compound represented by Formula H-1.

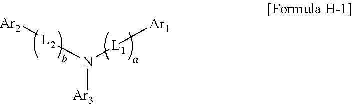

In Formula H-1, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. In Formula H-1, a and b may each independently be an integer from 0 to 10. If a or b is 2 or more, multiple L₁ groups and L₂ groups may each independently be a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. In Formula H-1, Arₙ may be a substituted or unsubstituted aryl group of 6 to 30 ring-forming carbon atoms or a substituted or unsubstituted heteroaryl group of 2 to 30 ring-forming carbon atoms.

In an embodiment compound represented by Formula H-1 may be a monoamine compound. In another embodiment, the compound represented by Formula H-1 may be a diamine compound in which at least one of Ar₁ to Ar₃ includes an amine group as a substituent. In yet another embodiment, the compound represented by Formula H-1 may be a carbazole-based compound in which at least one of Ar₁ and Ar₂ includes a substituted or unsubstituted carbazole group, or a fluorene-based compound in which at least one of Ar₁ and Ar₂ includes a substituted or unsubstituted fluorene group.

The compound represented by Formula H-1 may be any compound selected from Compound Group H. However, the compounds shown in Compound Group H are only examples, and a compound represented by Formula H-1 is not limited to Compound Group H.

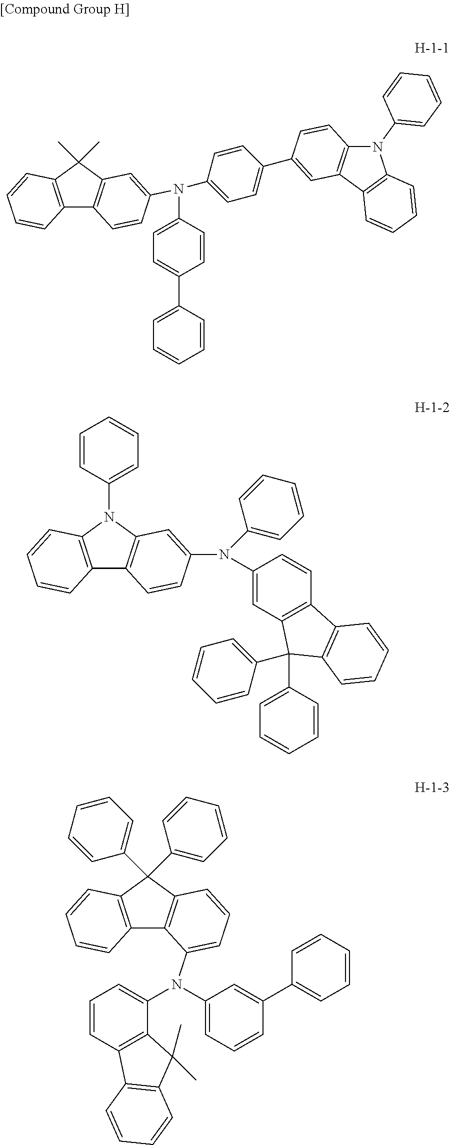 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

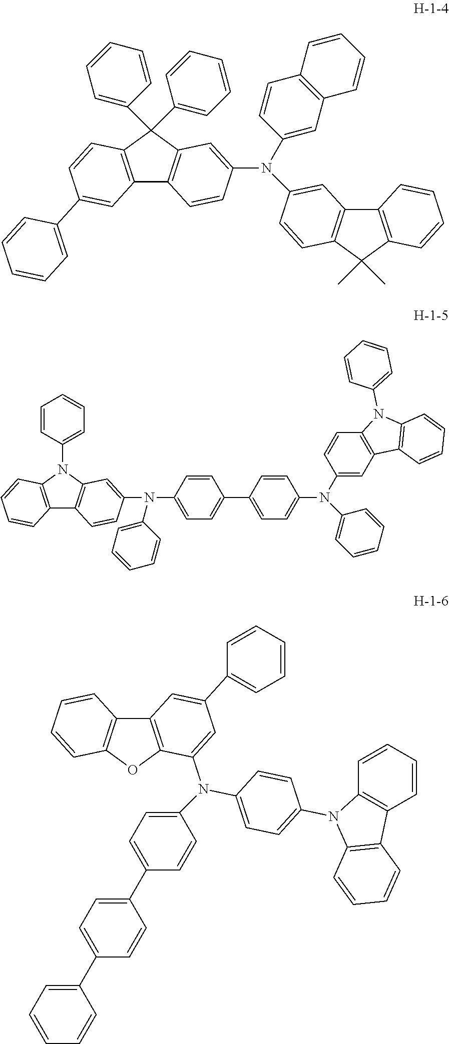 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

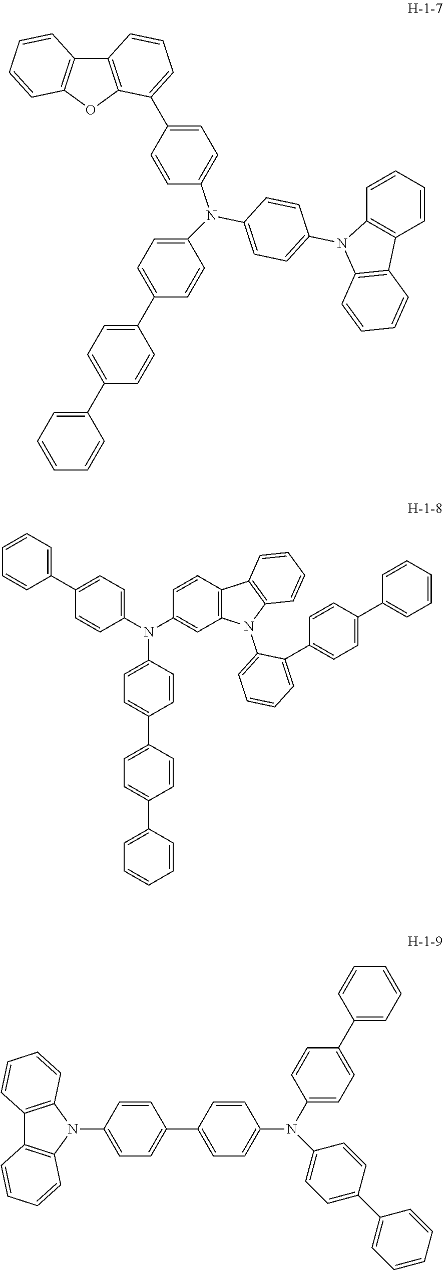 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

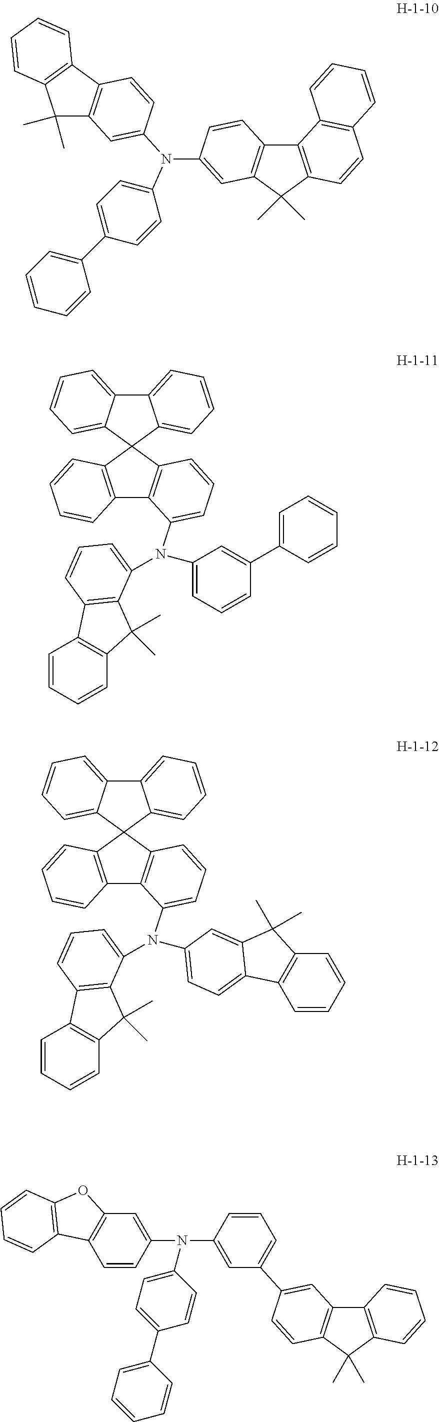 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

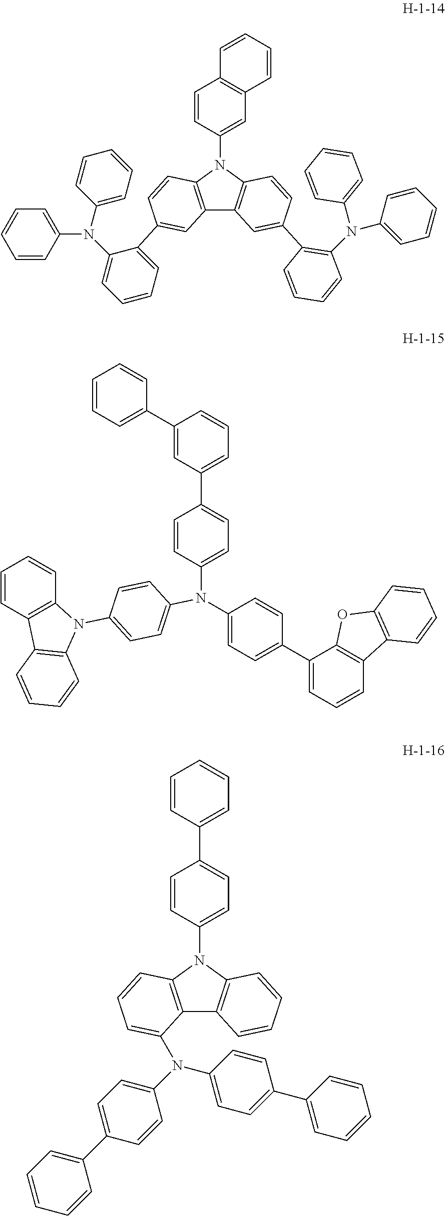 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

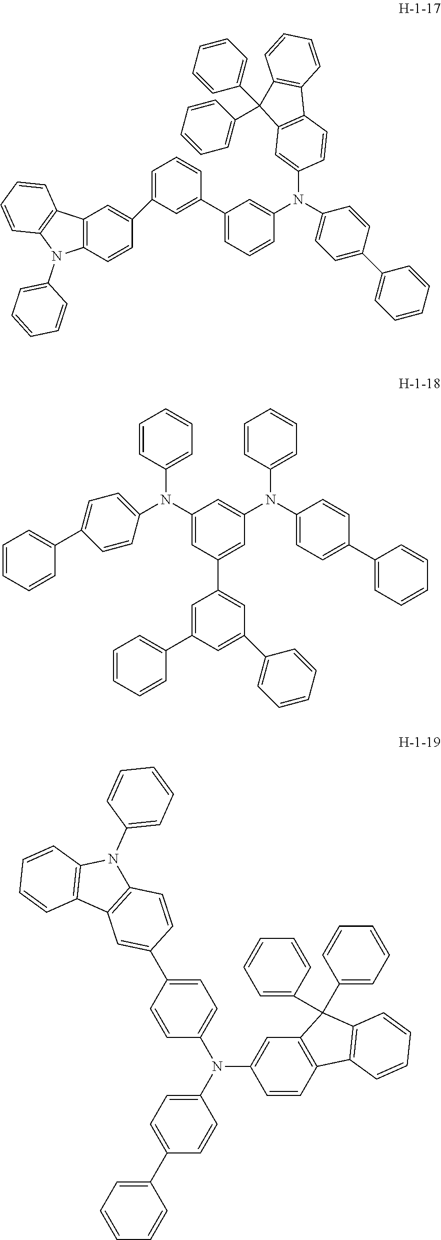 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

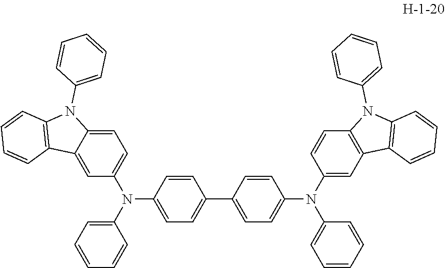 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

The first hole transport region HTR1 may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and dipyrazino[2,3-f:2′,3′-h]quinoxaline-2,3,6,7,10,11-hexacarbonitrile (HATCN).

The first hole transport region HTR1 may further include carbazole derivatives such as N-phenyl carbazole and polyvinyl carbazole, fluorene-based derivatives, triphenylamine-based derivatives such as N,N′-bis(3-methylphenyl)-N,N′-diphenyl-[1,1-biphenyl]-4,4′-diamine (TPD) and 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), or the like.

The first hole transport region HTR1 may further include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The first hole transport region HTR1 may include the compounds of the hole transport region in at least one of a first hole injection layer HIL1, a first hole transport layer HTL1, a first emission auxiliary layer SE-R1 and a first electron blocking layer (not shown).

A thickness of the first hole transport region HTR1 may be in a range of about 100 Å to about 10,000 Å. For example, the thickness of the first hole transport region HTR1 may be in a range of about 100 Å to about 5,000 Å. If the first hole transport region HTR1 includes a first hole injection layer HIL1, a thickness of the first hole injection region HIL may be, for example, in a range of about 30 Å to about 1,000 Å. If the first hole transport region HTR1 includes a first hole transport layer HTL1, a thickness of the first hole transport layer HTL1 may be in a range of about 30 Å to about 1,000 Å. If the first hole transport region HTR1 includes a first electron blocking layer (not shown), a thickness of the first electron blocking layer (not shown) may be in a range of about 10 Å to about 1,000 Å. If the thicknesses of the first hole transport region HTR1, the first hole injection layer HIL1, the first hole transport layer HTL1 and the first electron blocking layer (not shown) satisfy the above-described ranges, satisfactory hole transport properties may be achieved without substantial increase of a driving voltage.

The first hole transport region HTR1 may further include a p-dopant in addition to the above-described materials. The p-dopant may be dispersed uniformly or non-uniformly in the first hole transport region HTR1. The p-dopant may include at least one of metal halide compounds, quinone derivatives, metal oxides, and cyano group-containing compounds, without limitation. For example, the p-dopant may include metal halide compounds such as CuI and RbI, quinone derivatives such as tetracyanoquinodimethane (TCNQ) and 2,3,5,6-tetrafluoro-7,7′,8,8-tetracyanoquinodimethane (F4-TCNQ), metal oxides such as tungsten oxide and molybdenum oxide, cyano group-containing compounds such as dipyrazino[2,3-f: 2′,3′-h]quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., without limitation.

The first emission layer EML1 of the first light emitting unit OL1 may be provided on the first hole transport region HTR1. The first emission layer EML1 may include a first red emission layer EML-R1 that overlaps the first light emitting region PXA-R, a first green emission layer EML-G1 that overlaps the second light emitting region PXA-G, and a third blue emission layer that overlaps the third light emitting region PXA-B. The first emission layer EML1 may have a thickness in a range of about 100 Å to about 1000 Å. For example, the first emission layer EML 1 may have a thickness in a range of about 100 Å to about 300 Å. The first emission layer EML1 may be a layer consisting of a single material, a layer including different materials, or a structure including multiple layers including different materials.

The first emission layer EML1 may include anthracene derivatives, pyrene derivatives, fluoranthene derivatives, chrysene derivatives, dihydrobenzanthracene derivatives, or triphenylene derivatives. For example, the first emission layer EML1 may include anthracene derivatives or pyrene derivatives.

The first emission layer EML1 may be formed using various methods such as a vacuum deposition method, a spin coating method, a cast method, a Langmuir-Blodgett (LB) method, an inkjet printing method, a laser printing method, and a laser induced thermal imaging (LITI) method.

In an embodiment, the first emission layer EML1 may include a host and a dopant, and the first emission layer EML1 may include a compound represented by Formula E-1. For example, the first blue emission layer E-L-B1 may include the compound represented by Formula E-1. The compound represented by Formula E-1 may be used as a fluorescence host material.

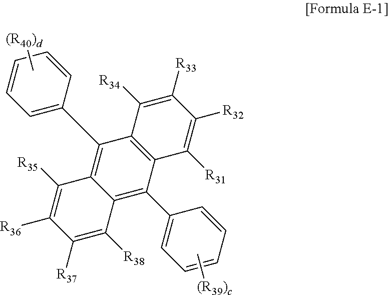

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or may be bonded to an adjacent group to form a ring. For example at least one of R₃₁ to R₄₀ may be combined with an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be selected from Compound E1 to Compound E19.

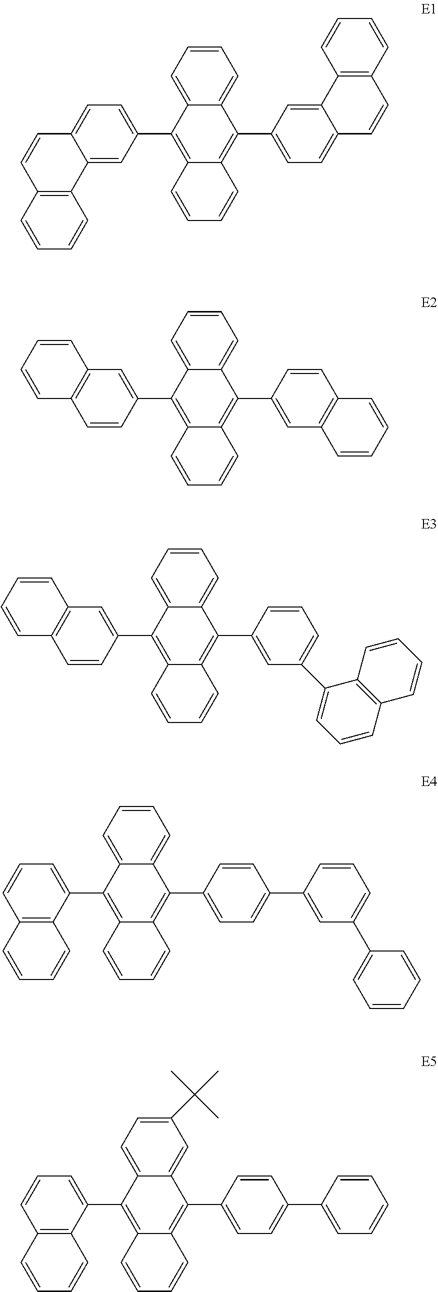

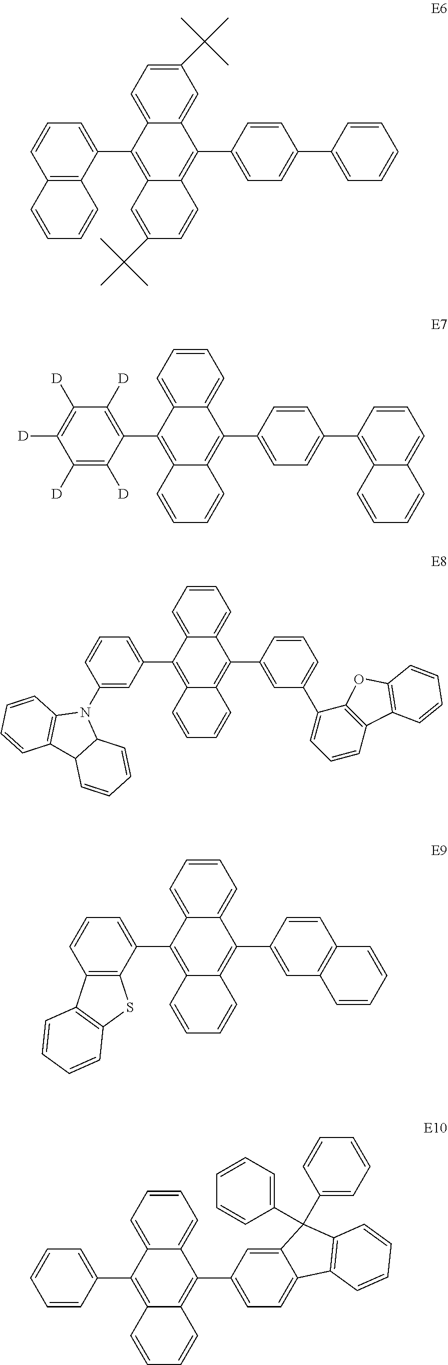

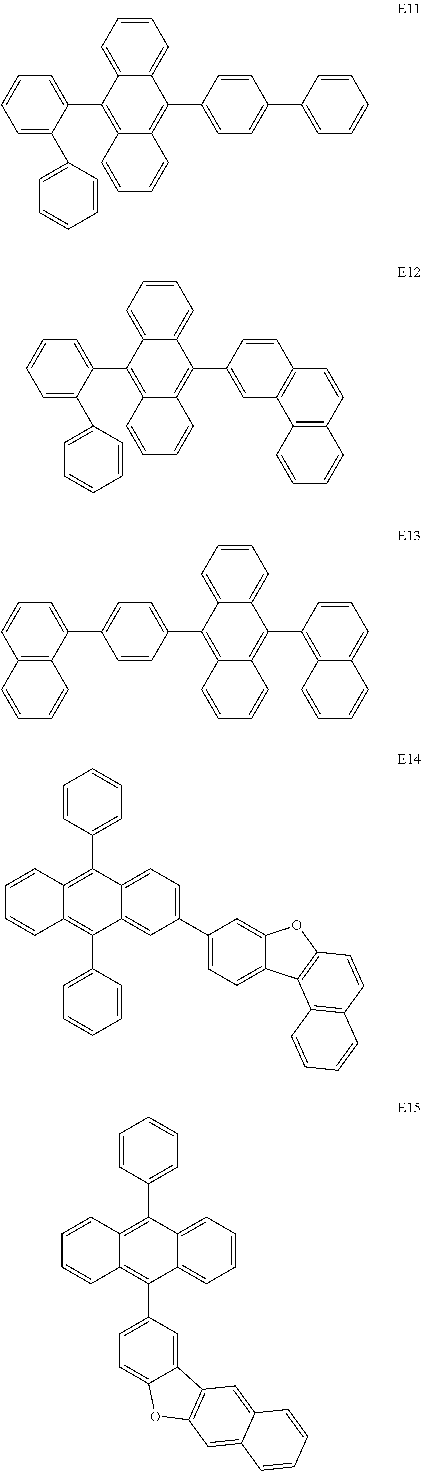

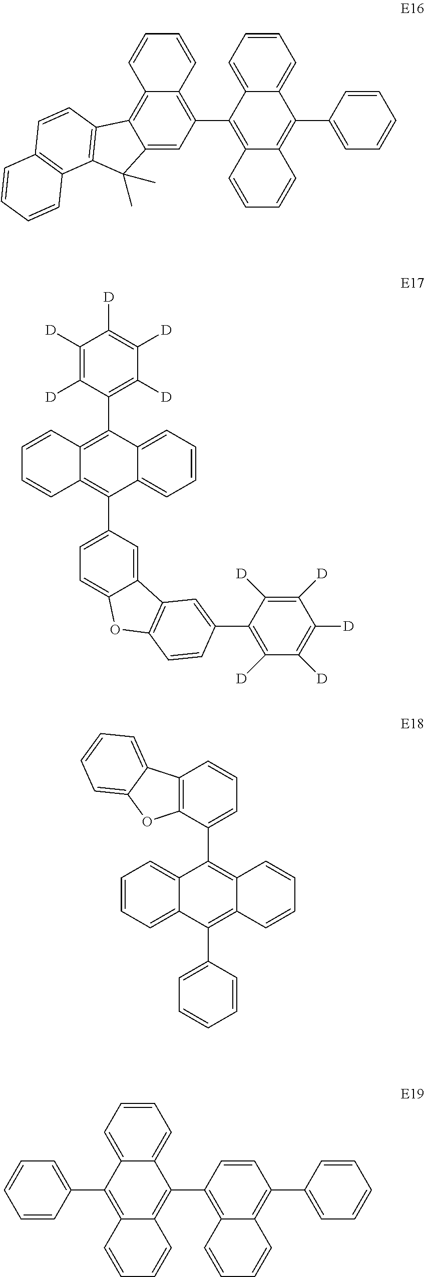

In an embodiment, the first emission layer EML1 may include a compound represented by Formula E-2a or Formula E-2b. For example, each of the first red emission layer EML-R1 and the first green emission layer EML-G1 may include the compound represented by Formula E-2a or Formula E-2b. The compound represented by Formula E-2a or Formula E-2b may be used as phosphorescence host material.

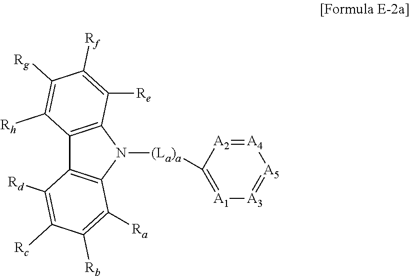

In Formula E-2a, a may be an integer from 0 to 10; and Lₐ may be a direct linkage, a substituted or unsubstituted arylene group of 6 to 30 ring-forming carbon atoms, or a substituted or unsubstituted heteroarylene group of 2 to 30 ring-forming carbon atoms. If a is 2 or more, multiple Lₐ groups may each independently be a substituted or unsubstituted arylene group of 6 to 30 ring-forming carbon atoms, or a substituted or unsubstituted heteroarylene group of 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be bonded to an adjacent group to form a ring. For example, each of Rₐ to Rᵢ may be combined with an adjacent group to form a hydrocarbon ring or a heterocycle including N, O, S, etc. as a ring-forming atom.

In Formula E-2a, two or three of A₁ to A₅ may each be N, and the remainder of A₁ to A₅ may each independently be C(Rᵢ).

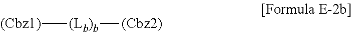

In Formula E-2b, Cbz1 and Cbz2 may each independently be an unsubstituted carbazole group, or a carbazole group substituted with an aryl group of 6 to 30 ring-forming carbon atoms. In Formula E-2b, L_{b} may be a direct linkage, a substituted or unsubstituted arylene group of 6 to 30 ring-forming carbon atoms, or a substituted or unsubstituted heteroarylene group of 2 to 30 ring-forming carbon atoms. In Formula E-2b, b may be an integer from 0 to 10, and if b is 2 or more, multiple L_{b} groups may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be a compound selected from Compound Group E-2. However, the compounds shown in Compound Group E-2 are only examples, and the compound represented by Formula E-2a or Formula E-2b is not limited to Compound Group E-2.

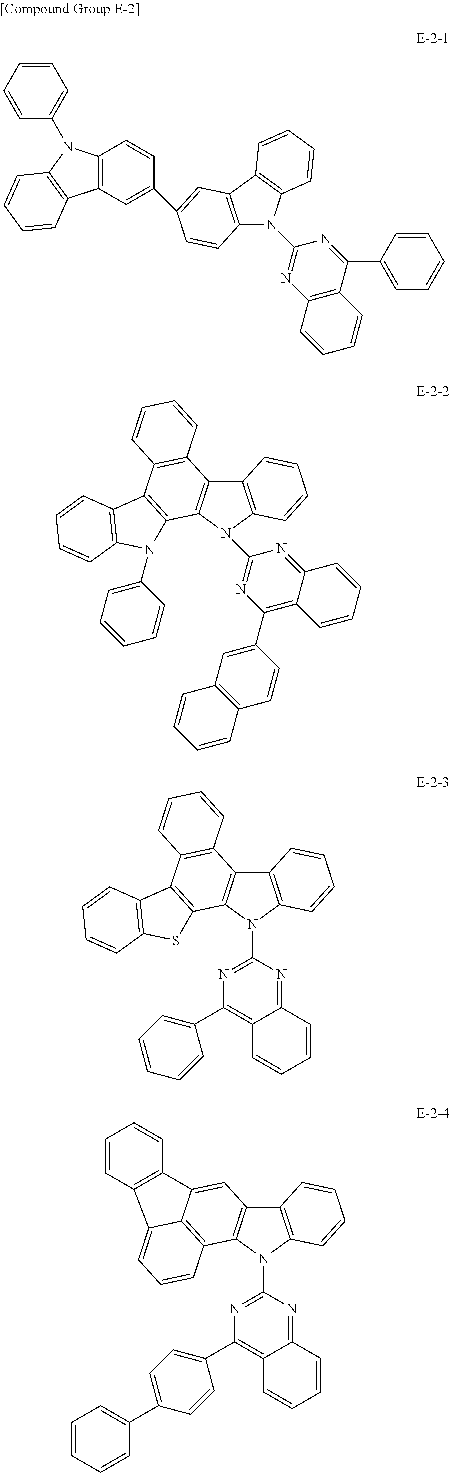

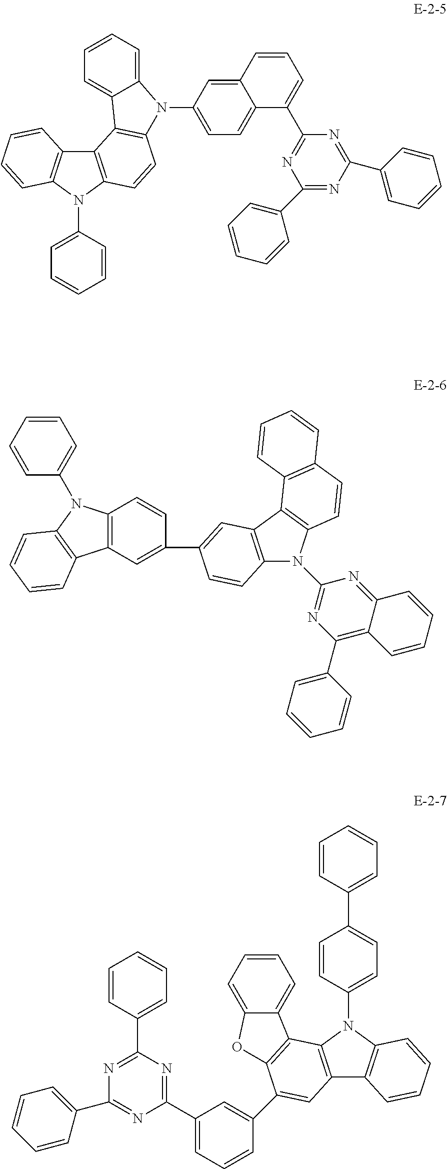 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

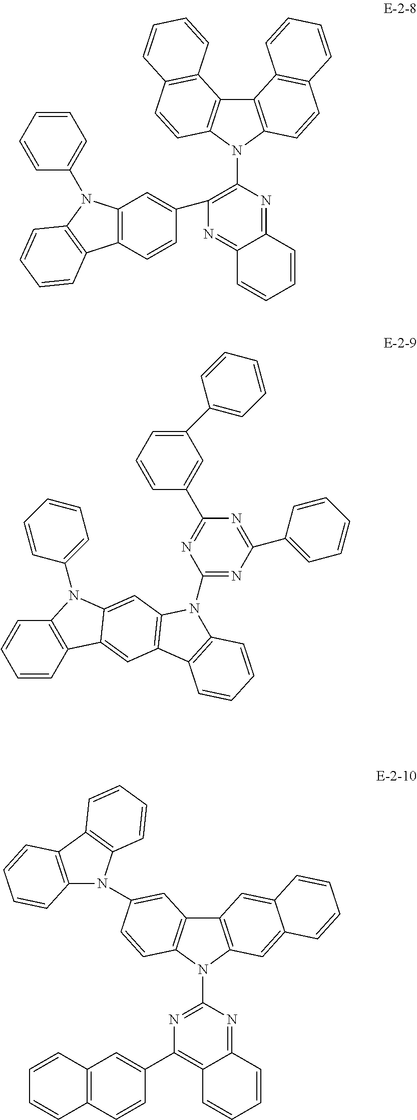 [SMILES: c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

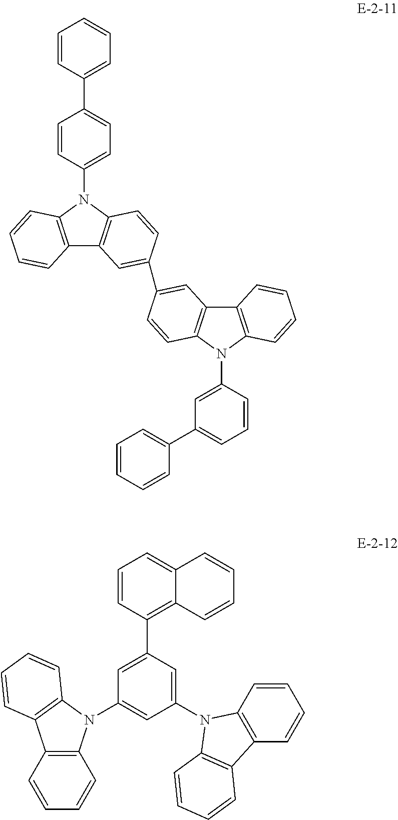 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

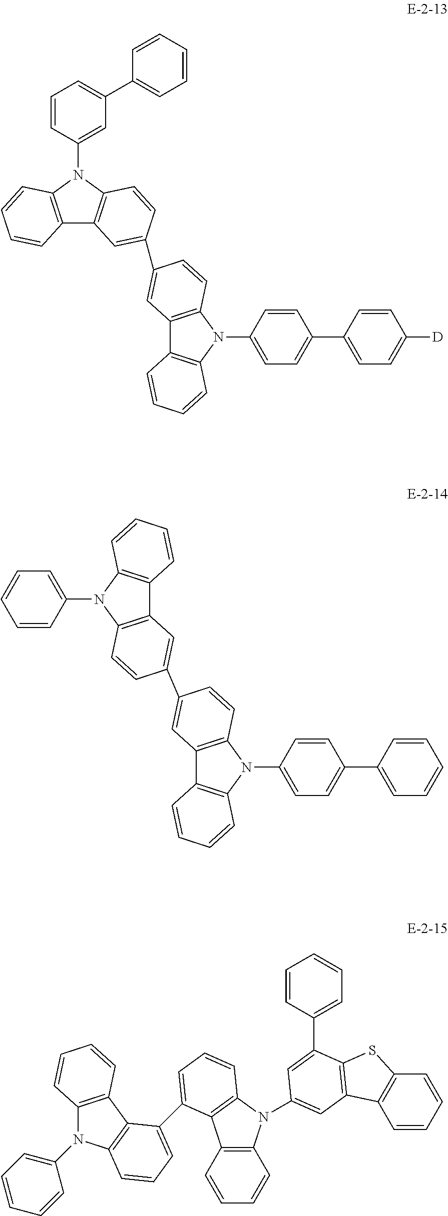 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

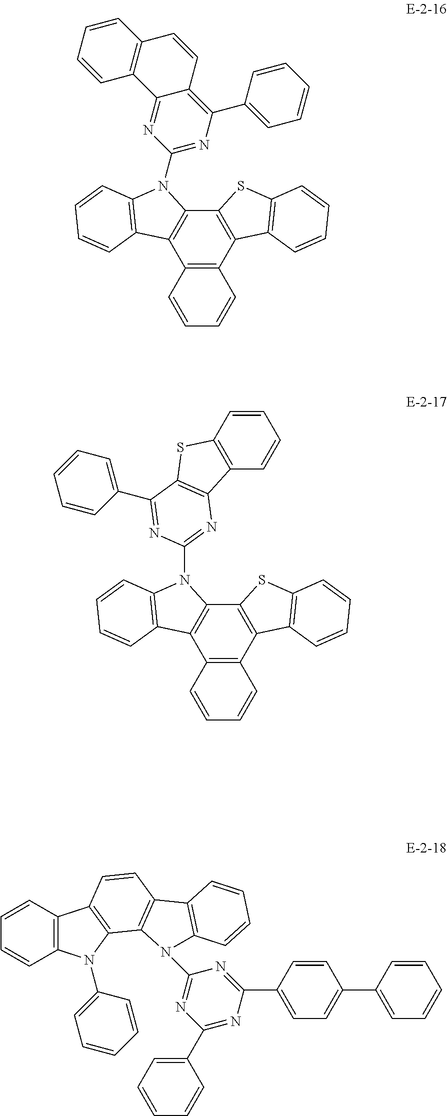 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

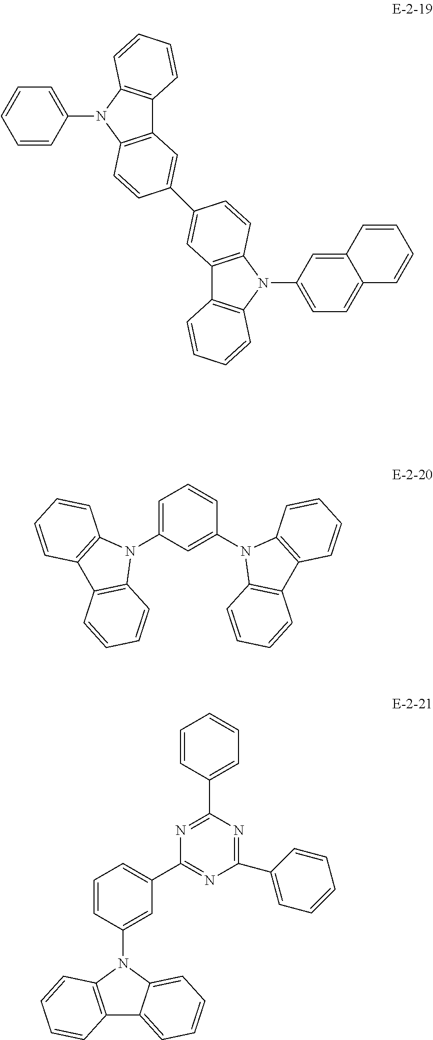 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

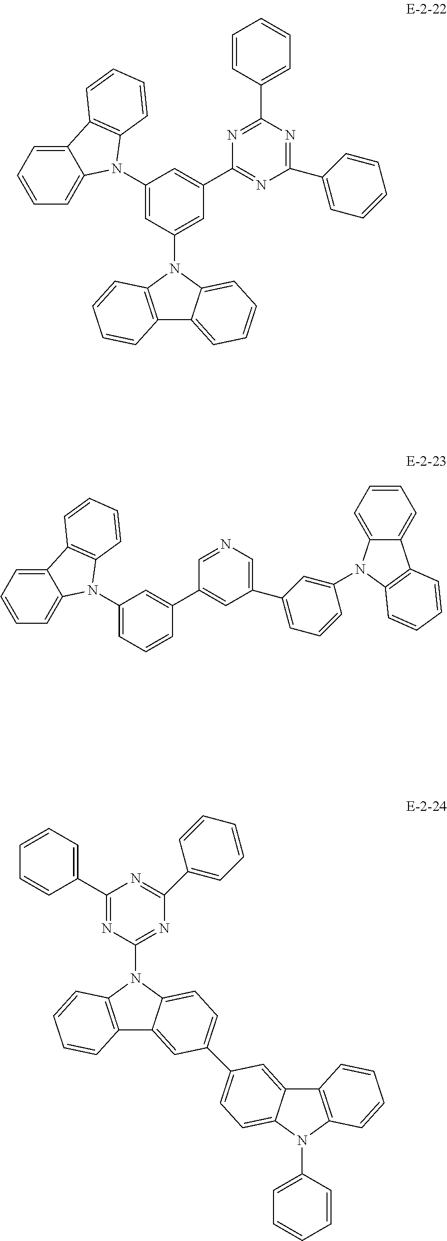 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The first emission layer EML1 may further include a common material of the related art as a host material. For example, the first emission layer EML1 may include as a host material, at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP). 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

In an embodiment, the first emission layer EML1 may include a compound represented by Formula M-a. For example, each of the red emission layer EML-R1 and the first green emission layer EML-G1 may include the compound represented by Formula M-a. The compound represented by Formula M-a may be used as a phosphorescence dopant material.

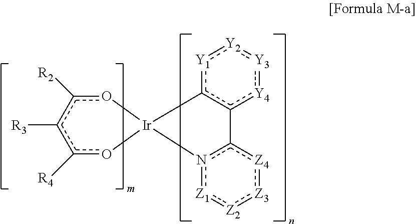

In Formula M-a, Y₁ to Y₄, and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be bonded to an adjacent group to form a ring. In Formula M-a, m may be 0 or 1, and n may be 2 or 3. In Formula M-a, if m is 0, n may be 3, and if m is 1, n may be 2.

The compound represented by Formula M-a may be any compound selected from Compounds M-a1 to M-a25. However, Compounds M-a1 to M-a25 are only examples, and the compound represented by Formula M-a is not limited to Compounds M-a1 to M-a25.

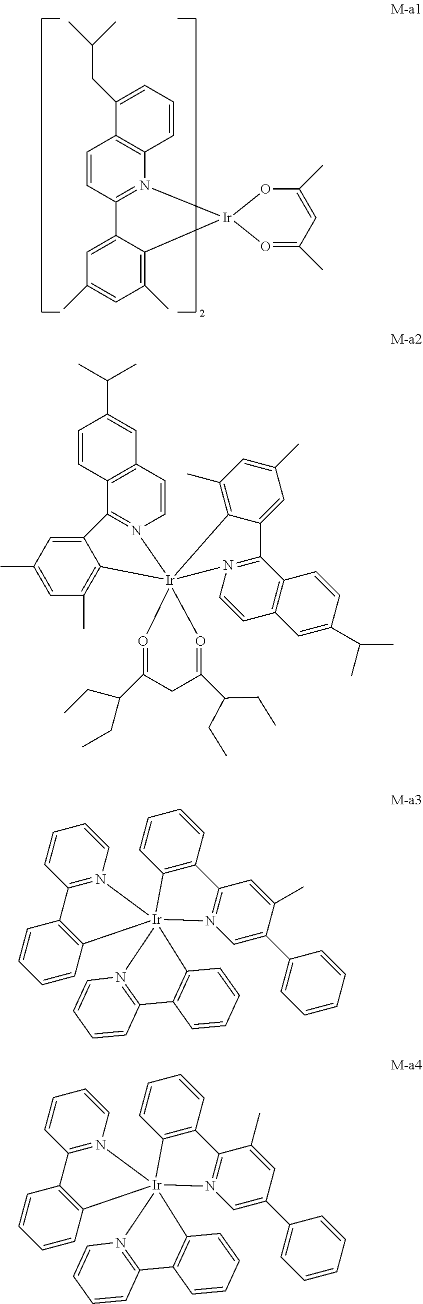

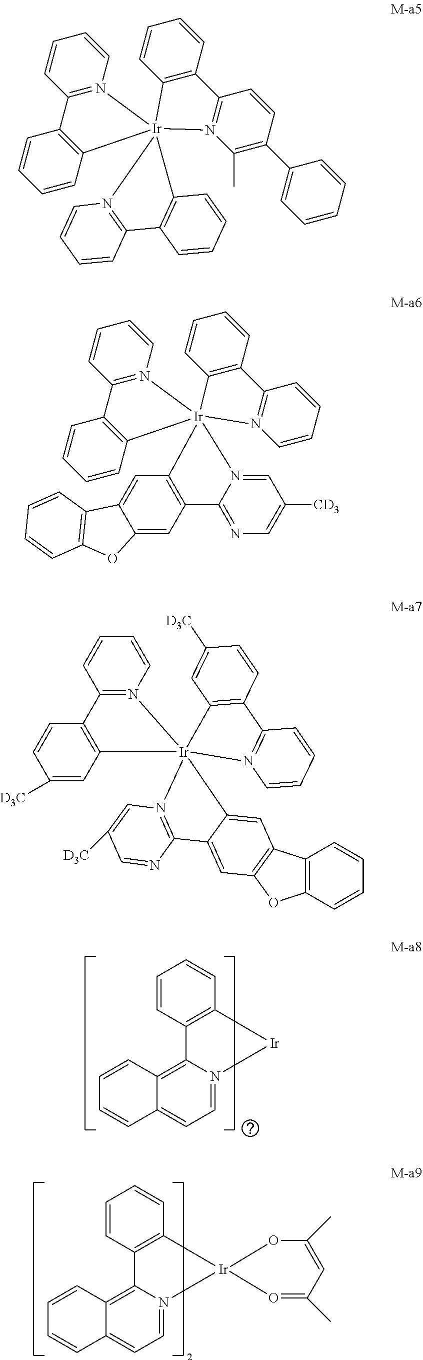

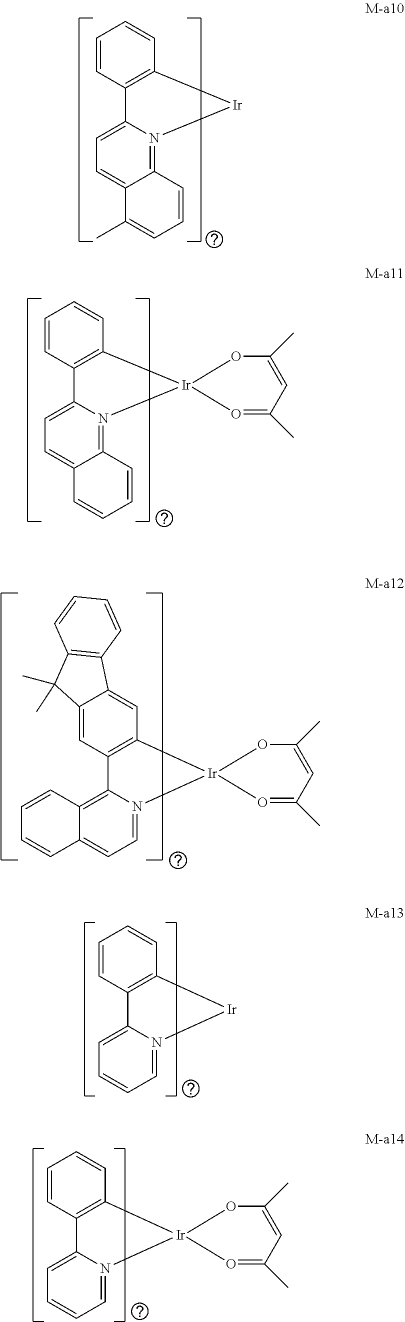

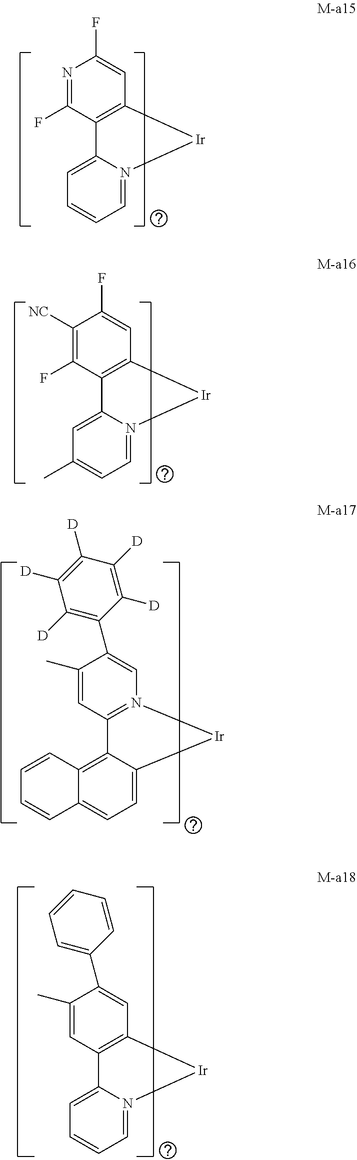

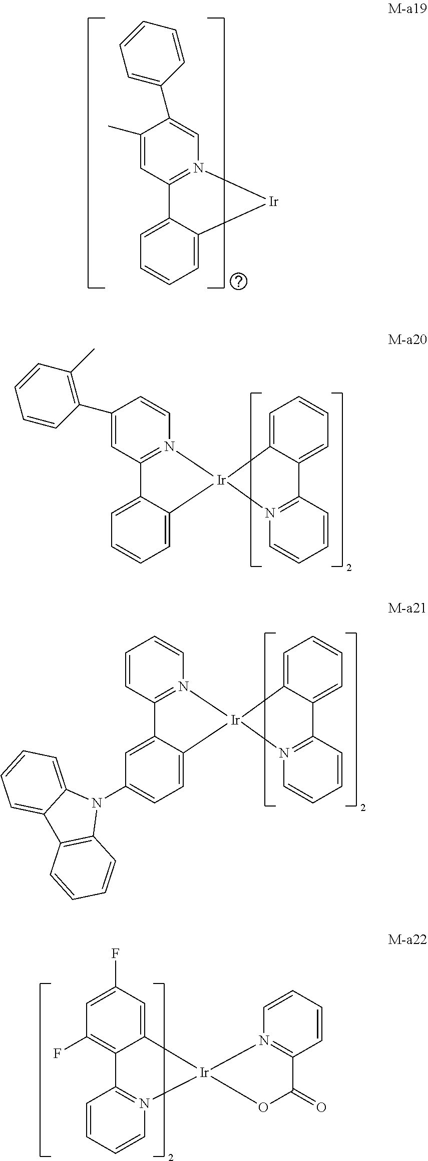

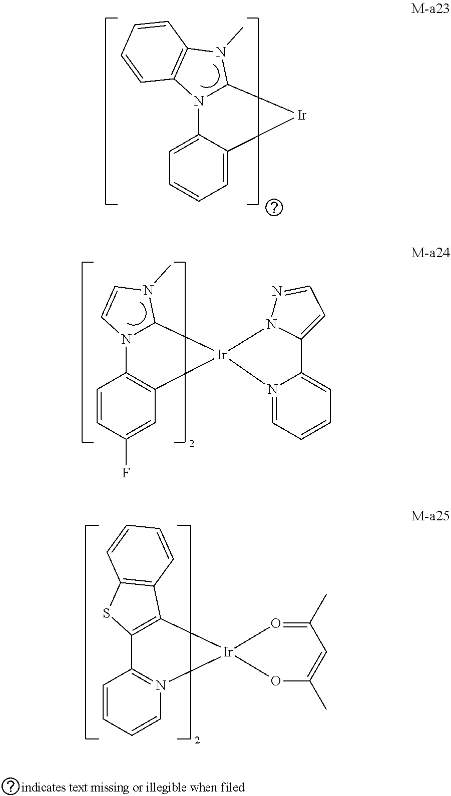

In embodiments, the first emission layer EML1 may include a compound represented by one of Formula F-a to Formula F-c. For example, the first blue emission layer EML-B1 may include the compound represented by one of Formula F-a to Formula F-c. The compounds represented by Formula F-a to Formula F-c may be used as fluorescence dopant materials.

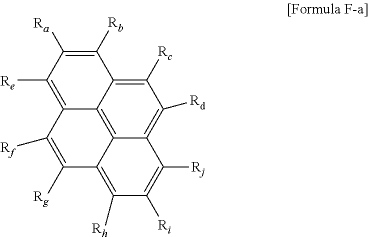

In Formula F-a, two of Rₐ to Rⱼ may each independently be substituted with a group represented by

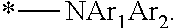

The remainder of Rₐ to Rⱼ which are not substituted with the group represented by

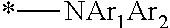

may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In the group represented by

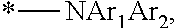

Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one of Ar₁ and Ar₂ may each independently be a heteroaryl group including O or S as a ring-forming atom.

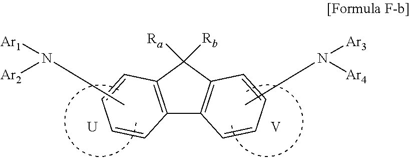

In Formula F-b, Rₐ and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be bonded to an adjacent group to form a ring. In Formula F-b, Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms. For example, at least one of Ar₁ to Ar₄ may each independently be a heteroaryl group including O or S as a ring-forming atom.

In Formula F-b, U and V may be each independently be a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may each independently be 0 or 1. If the number of U or V is 1, a fused ring may be present at the portion indicated by U or V, and if the number of U or V is 0, a fused ring may not be present at the portion indicated by U or V. If the number of U is 0, and the number of V is 1, or if the number of U is 1 and the number of V is 0, a fused ring having the fluorene core of Formula F-b may be a cyclic compound with four rings. If the number of U and V is 0, a fused ring of Formula F-b may be a cyclic compound with three rings. If the number of both U and V is each 1, a fused ring having the fluorene core of Formula F-b may be a cyclic compound with five rings.

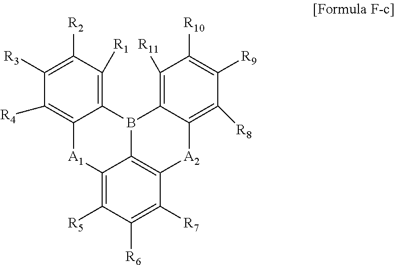

In Formula F-c, A₁ and A₂ may each independently be O, S, Se, or N(Rₘ); and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, a substituted or unsubstituted heteroaryl group of 2 to 30 ring-forming carbon atoms, or bonded to an adjacent group to form a ring.

In Formula F-c, A₁ and A₂ may each independently be combined with a substituent of an adjacent ring to form a fused ring. For example, if A₁ and A₂ are each independently N(Rₘ), Aᵢ may be bonded to R₄ or R₅ to form a ring. For example, A₂ may be combined with R₇ or R₈ to form a ring.

In an embodiment, the first emission layer EML1 may further include as a dopant material of the related art, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and 1,4-bis(N,N-diphenylamino)pyrene), etc.

The first emission layer EML1 may further include a phosphorescence dopant material of the related art. For example, the phosphorescence dopant may be a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP). However, embodiments are not limited thereto.

The first emission layer EML1 may include a quantum dot material. The quantum dot may be a Group II-VI compound, a Group III-VI compound, a Group I-III-VI compound, a Group III-V compound, a Group III-II-V compound, a Group IV-VI compound, a Group IV element, a Group IV compound, and any combination thereof.

Examples of a Group II-VI compound may include: a binary compound selected from the group consisting of CdSe, CdTe, CdS, ZnS, ZnSe, ZnTe, ZnO, HgS, HgSe, HgTe, MgSe, MgS, and mixtures thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof; or any combination thereof.

Examples of a Group III-VI compound may include: a binary compound such as In₂S₃, and In₂Se₃; a ternary compound such as InGaS₃, and InGaSe₃; or any combination thereof.

Examples of a Group 1-III-VI compound may include: a ternary compound selected from the group consisting of AgInS, AgInS₂, CuInS, CuInS2, AgGaS₂, CuGaS₂, CuGaO₂, AgGaO₂, AgAlO₂ and mixtures thereof, or a quaternary compound such as AgInGaS₂, and CuInGaS₂; or any combination thereof.

Examples of a Group III-V compound may include: a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof, or any combination thereof. In an embodiment, a Group III-V group compound may further include a Group II metal. Examples of a Group III-II-V compound may include InZnP, etc.

Examples of a Group IV-VI group compound may include: a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, a quaternary compound selected from the group consisting of SnPbSSe, SnPbSeTe, SnPbSTe, and mixtures thereof, or any combination thereof. Examples of a Group IV element may include Si, Ge, and a mixture thereof. Examples of a Group IV compound may be a binary compound selected from the group consisting of SiC, SiGe, and a mixture thereof.

Each element included in the polynary compound such as the binary compound, the ternary compound and the quaternary compound may be present at uniform concentration or at non-uniform concentration in a particle. For example, a chemical formula may indicate elements included in a compound, but a ratio of elements in the compound may vary. For example, AgInGaS₂ may mean AgInₓGa₁₋ₓS₂ (where x is a real number between 0 and 1).

In embodiments, the quantum dot may have a single structure in which the concentration of each element included in the quantum dot is uniform, or a quantum dot may have a core-shell structure. For example, a material included in the core and a material included in the shell may be different from each other.

The shell of the quantum dot may serve as a protection layer for preventing the chemical deformation of the core to maintain semiconductor properties and/or may serve as a charging layer for imparting the quantum dot with electrophoretic properties. The shell may have a single layer or a multilayer. An interface between the core and the shell may have a concentration gradient in which the concentration of an element that is present in the shell decreases toward the core.

In embodiments, the quantum dot may have the above-described core-shell structure including a core that includes a nanocrystal and a shell surrounding the core. Examples of the shell of the quantum dot may include a metal oxide or a non-metal oxide, a semiconductor compound, or any combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO; or a ternary compound such as MgAl₂O₄, CoFe₂O₄, NiFe₂O₄ and CoMn₂O₄. However, embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width of half maximum (FWHM) of an emission spectrum equal to or less than about 45 nm. For example, the quantum dot may have a FWHM of an emission spectrum equal to or less than about 40 nm. For example, the quantum dot may have a FWHM of an emission spectrum equal to or less than about 30 nm. Within any of the above ranges, color purity or color reproducibility may be improved. Light emitted through a quantum dot may be emitted in all directions, so that light view angle properties may be improved.

The shape of a quantum dot may be any shape that is used in the related art. For example, a quantum dot may have a spherical shape, a pyramidal shape, a multi-arm shape, or a cubic shape, or the quantum dot may be in the form of a nanoparticle, a nanotube, a nanowire, a nanofiber, a nanoplate particle, etc.

By controlling the size of a quantum dot or by controlling the ratio of elements in a quantum dot compound, an energy band gap may be controlled, and various wavelength bands of light may be obtained from a quantum dot emission layer. Accordingly, by using quantum dots (for example, using quantum dots having different sizes or controlling the ratio of elements in a quantum dot compound differently), a light emitting element that emits various wavelengths of light may be achieved. For example, the size of the quantum dot or the ratio of elements in the quantum dot compound may be adjusted to emit red, green and/or blue light. For example, the quantum dots may be configured to emit white light by combining light of various colors.

The first electron transport region ETR1 of the first light emitting unit OL1 may be provided on the first emission layer EML1. The first electron transport region ETR1 may include at least one of a first electron blocking layer (not shown), a first electron transport layer ETL1 or a first electron injection layer EIL1. However, embodiments are not limited thereto.

The first electron transport region ETR1 may be a layer consisting of a single material, a layer including different materials, or a structure including multiple layers including different materials.

For example, the first electron transport region ETR1 may have a single layer structure of a first electron injection layer EIL1 or a first electron transport layer ETL1, or may have a single layer structure formed using an electron injection material and an electron transport material. In other embodiments, the first electron transport region ETR1 may have a single layer structure formed of different materials, or may have a structure stacked from the first emission layer EHL1 of first electron transport layer ETL1/first electron injection layer EIL1, first hole blocking layer HBL1 (not shown)/first electron transport layer ETL1/first electron injection layer EIL1, or the like, without limitation. A thickness of the first electron transport region ETR1 may be, for example, in a range of about 1,000 Å to about 1,500 Å.

The first electron transport region ETR1 may be formed using various methods such as a vacuum deposition method, a spin coating method, a cast method, a Langmuir-Blodgett (LB) method, an inkjet printing method, a laser printing method, and a laser induced thermal imaging (LITI) method.

The first electron transport region ETR1 may include a compound represented by Formula ET-1.

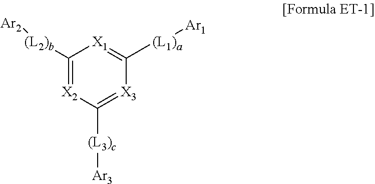

In Formula ET-1, at least one of X₁ to X₃ may each be N, and the remainder of X₁ to X₃ may each independently be C(Rₐ). In Formula ET-1, Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In Formula ET-1, Arᵢ to Arₙ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If a to c are 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The first electron transport region ETR1 may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenziimidazol-1-ylphenyl)-9,10-dinaphthylanthracene, 1,3,5-tri(1-phenyl-1H-benz[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), and mixtures thereof, without limitation.

The first electron transport region ETR1 may include at least one of Compounds ET1 to ET38.

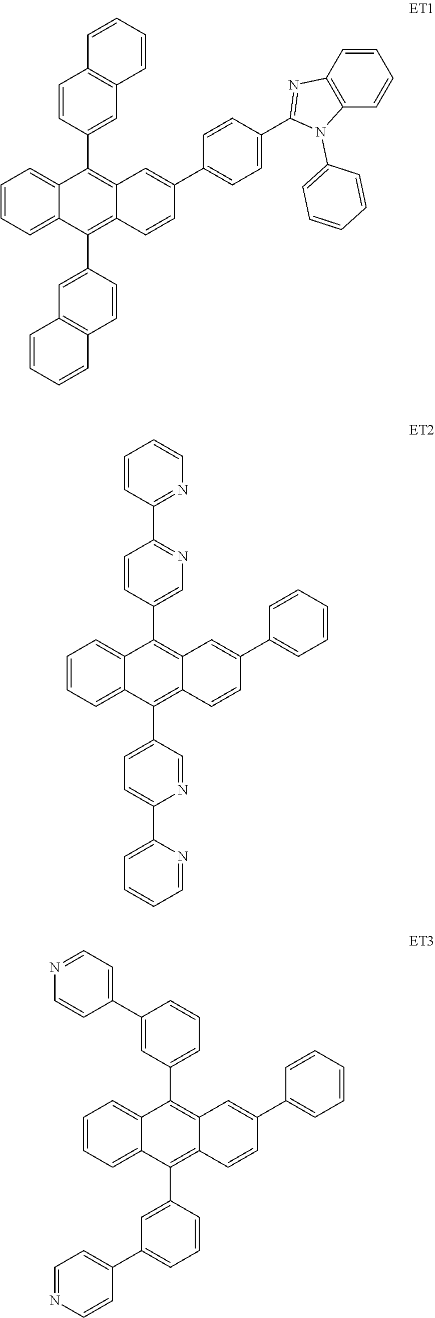 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

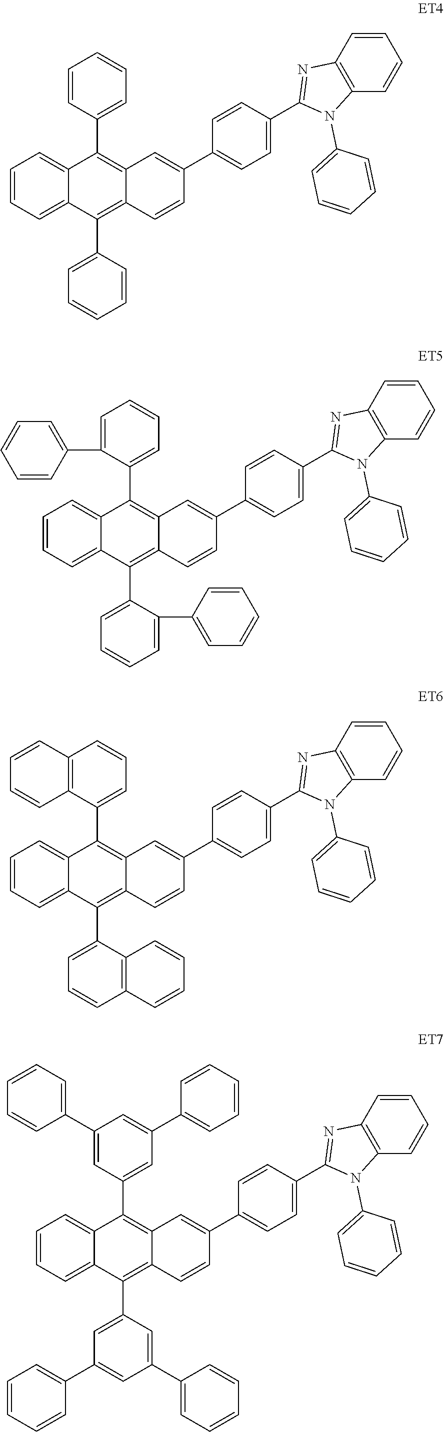 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

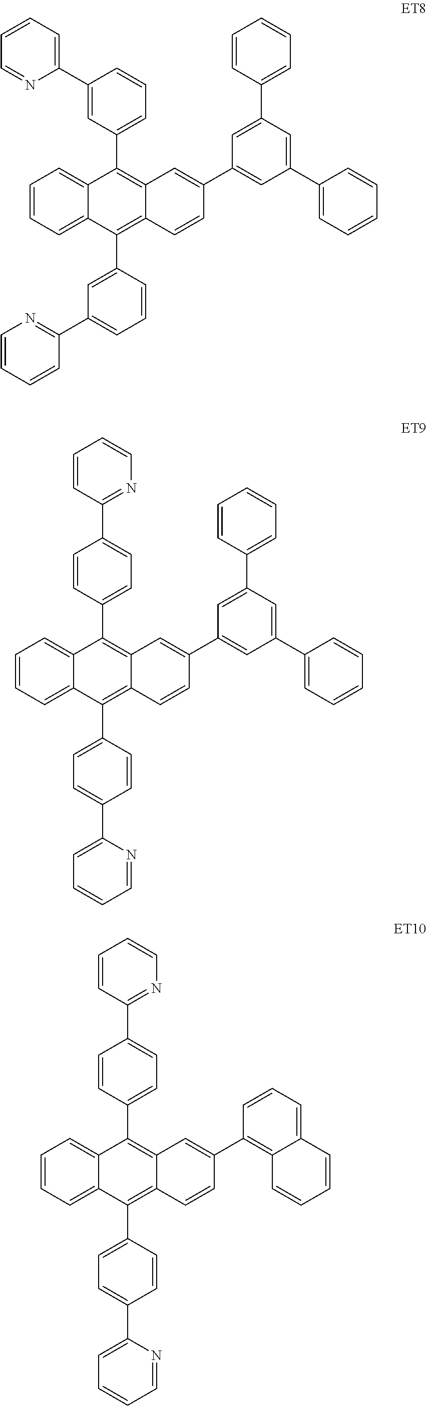

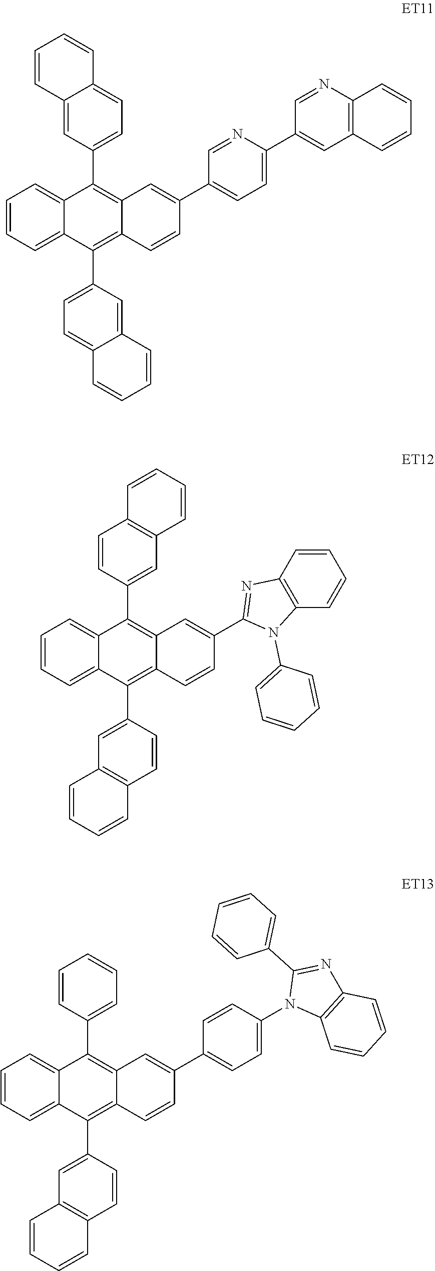 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

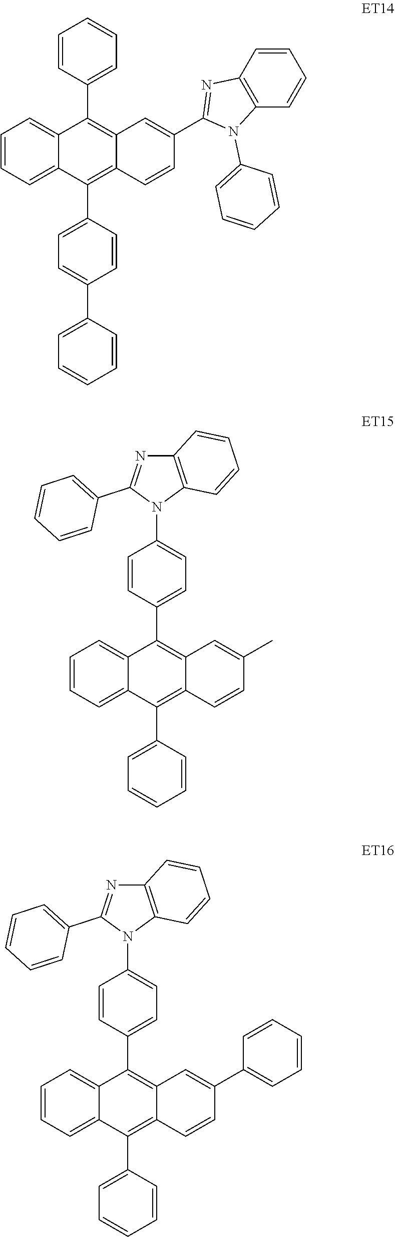 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

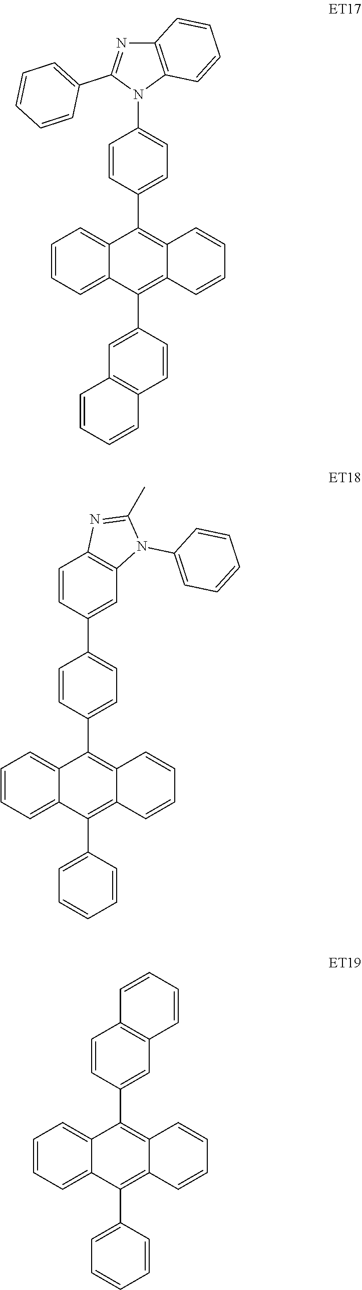

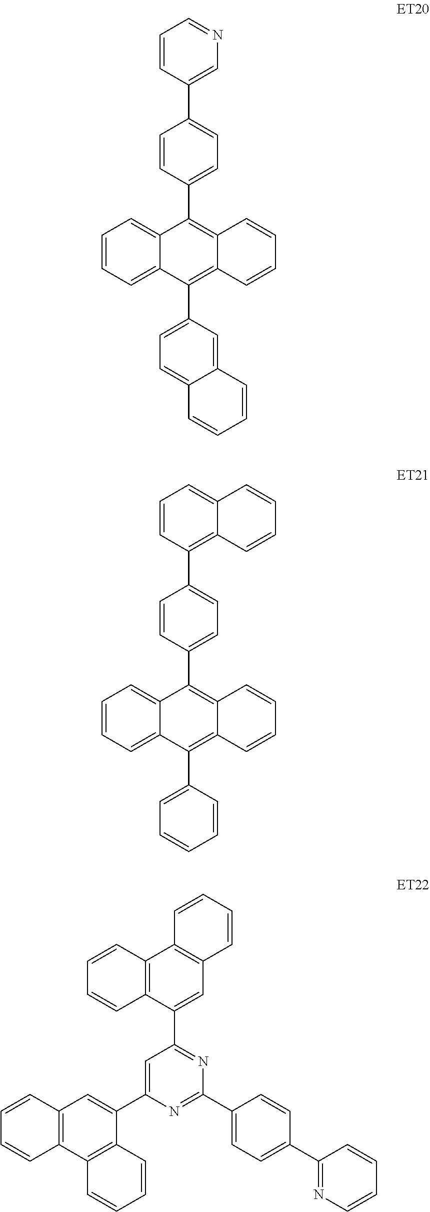

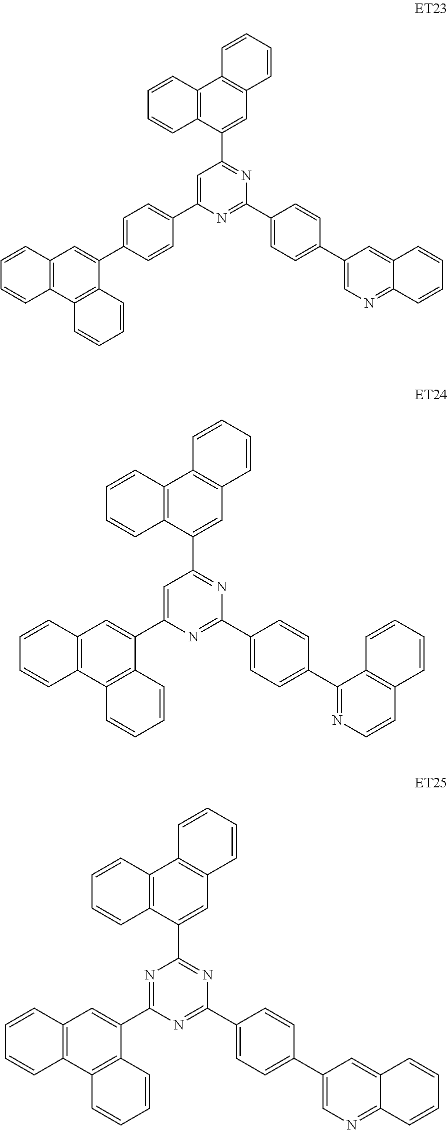 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

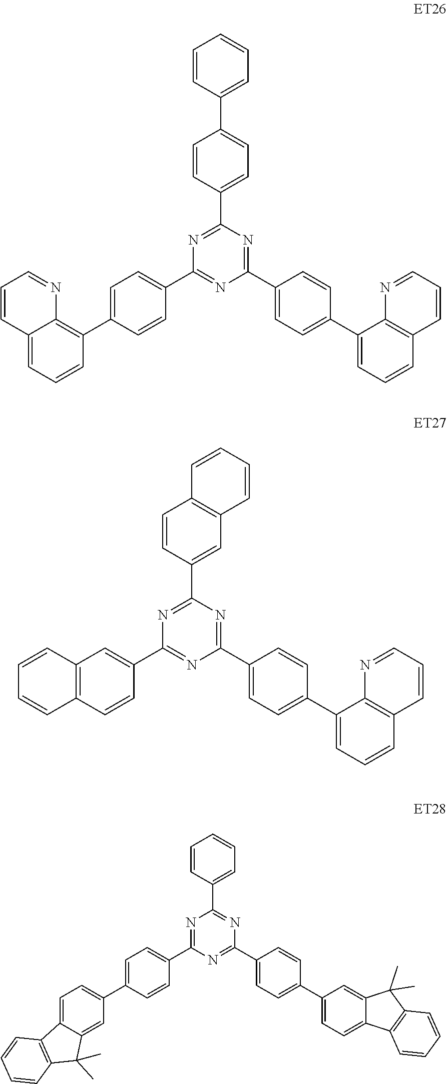 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

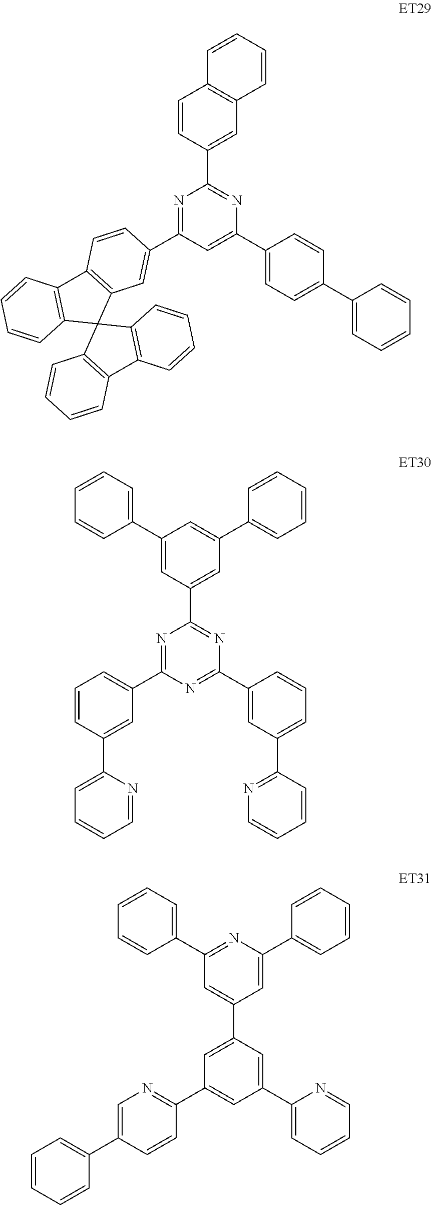 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

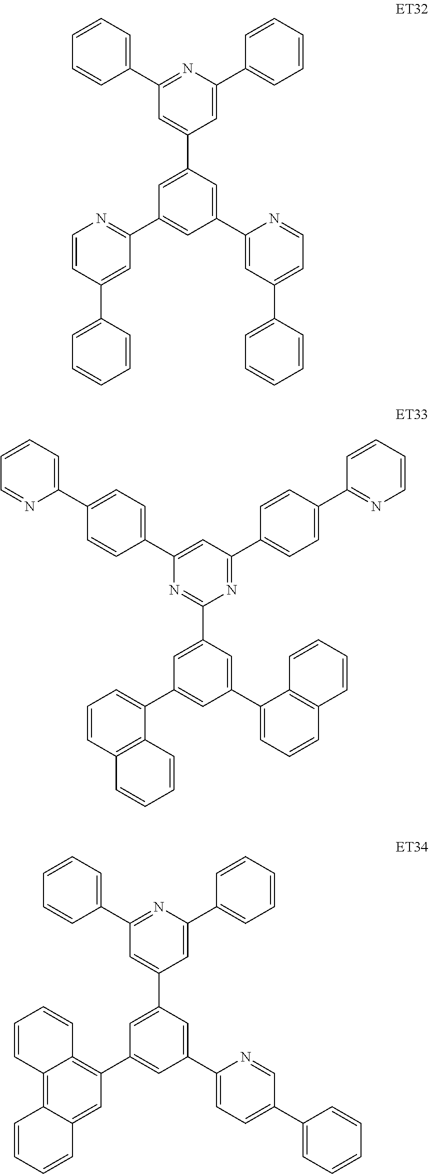 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

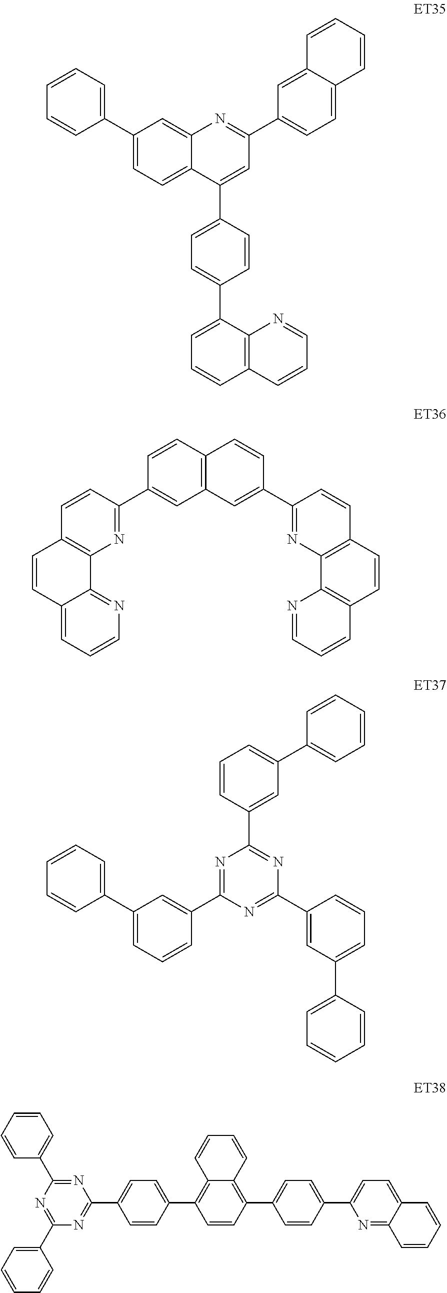

In an embodiment, the first electron transport region ETR1 may include a metal halide such as LiF, NaCl, CsF, RbCl, RbI, CuI and KI; and lanthanide metal such as Yb; or a co-deposited material of a metal halide and a lanthanide metal. For example, the first electron transport region ETR1 may include KI:Yb, RbI:Yb, LiF:Yb, etc., as the co-deposited material. The electron transport region ETR may use a metal oxide such as Li₂O and BaO, or 8-hydroxy-lithium quinolate (Liq). However, embodiments are not limited thereto. The electron transport region ETR also may be formed using a mixture material of an electron transport material and an insulating organometallic salt. The organometallic salt may be a material having an energy band gap equal to or greater than about 4 eV. For example, the organometallic salt may include metal acetates, metal benzoates, metal acetoacetates, metal acetylacetonates, or metal stearates.

The first electron transport region ETR1 may further include at least one of 2,9-dimethyl-4,7-diphenyl-1,10-phenanthroline (BCP), diphenyl(4-(triphenylsilyl)phenyl)phosphine oxide (TSPO1) an 4,7-diphenyl-1,10-phenanthroline (Bphen) in addition to the aforementioned materials. However, embodiments are not limited thereto.

The first electron transport region ETR1 may include the compounds of the electron transport region in at least one of a first electron injection layer EIL1, a first electron transport layer ETL1, and a first hole blocking layer (not shown).

If the first electron transport region ETR1 includes a first electron transport layer ETL1, a thickness of the first electron transport layer ETL1 may be in a range of about 100 Å to about 1,000 Å. For example, the first electron transport layer may have a thickness in a range of about 150 Å to about 500 Å. If the thickness of the first electron transport layer ETL1 satisfies any of the above-described ranges, satisfactory electron transport properties may be obtained without substantial increase of a driving voltage. If the first electron transport region ETR1 includes a first electron injection layer EIL1, a thickness of the first electron injection layer EIL1 may be from about 1 Å to about 100 Å. For example, the thickness of the first electron injection layer EIL 1 may be in a range of about 3 Å to about 90 Å. If the thickness of the first electron injection layer EIL1 satisfies any of the above described ranges, satisfactory electron injection properties may be obtained without inducing substantial increase of a driving voltage.

A charge generation unit CGL may be provided on the first light emitting unit OL1. The charge generation unit CGL may be provided on the first electron transport region ETR1 of the first light emitting unit OL1.

If a voltage is applied to the charge generation unit CGL, a complex may be formed through an oxidation-reduction reaction, and charges (electrons and holes) may be produced. The charge generation unit CGL may provide the produced charges to adjacent light emitting units OL1 and OL2. The charge generation unit CGL may increase the efficiency of current generated at each of the adjacent light emitting units OL1 and OL2, and may control the balance of charges between the adjacent light emitting units OL1 and OL2.

The charge generation unit CGL may include an aryl amine-based material or a metal oxide. For example, the charge generation unit CGL may include charge generating materials including an aryl amine-based organic compound, a carbazole-based compound, a metal, a metal oxide, a carbide, a fluoride, or mixtures thereof.

In an embodiment, the aryl amine-based organic compound may be the first compound according to an embodiment. The aryl amine-based organic compound may be the first compound represented by Formula 1 according to an embodiment. In the light emitting element ED according to an embodiment, at least one of the first hole transport region HTR1 and the charge generation unit CGL may each independently include the first compound. In other embodiments, the aryl amine-based organic compound may be N,N′-di(naphthalene1-yl)-N,N′-diphenyl-benzidine (αNPD), 4,4′,4″-tris[N(2-naphthyl)-N-phenylamino]-triphenylamine (2-TNATA), 4,4′4″-tris(N,N-diphenylamino)triphenylamine (TDATA), 4,4′,4″-[tris(3-methylphenyl)phenylamino]triphenylamine) (m-TDATA), spiro-TAD, or spiro-NPB. The carbazole-based compound may be 4,4′-bis(carbazol-9-yl)biphenyl (CBP). For example, the metal may be cesium (Cs), molybdenum (Mo), vanadium (V), titanium (Ti), tungsten (W), barium (Ba), or lithium (Li). For example, the metal oxide and the carbide may be Re₂O₇, MoO₃, V₂O₅, WO₃, TiO₂, or Cs₂CO₃. For example, the fluoride may be a perfluorodecalin-based fluoride, malonitrile-based fluoride, BaF, LiF or CsF.

The charge generation unit CGL may include a p-type charge generation layer p-CGL and an n-type charge generation layer n-CGL. The charge generation layer CGL may have a structure in which the p-type charge generation layer p-CGL and the n-type charge generation layer n-CGL are joined with each other. The charge generation layer CGL may have a structure of the p-type charge generation layer p-CGL and the n-type charge generation layer n-CGL in that order.

The n-type charge generation layer n-CGL may be a charge generation layer that provides electrons to adjacent light emitting units OL1 and OL2. The n-type charge generation layer n-CGL may include an n-dopant. The n-type charge generation layer n-CGL may be a layer in which an n-dopant is doped in a base material. The p-type charge generation layer n-CGL may be a charge generation layer that provides holes to adjacent light emitting units OL1 and OL2. The p-type charge generation layer p-CGL may include a p-dopant. The p-type charge generation layer p-CGL may be a layer in which a p-dopant is doped in a base material. In an embodiment, the p-type charge generation layer p-CGL may include the first compound according to an embodiment as a host, and may be a layer in which a p-dopant is doped in the host. Although not shown in the drawings, a buffer layer may be further disposed between the n-type charge generation layer n-CGL and the p-type charge generation layer p-CGL.

A thickness of the charge generation unit CGL may be in a range of about 100 Å to about 10000 Å. For example, the thickness of the charge generation unit CGL may be in a range of about 200 Å to about 5000 Å. If the charge generation unit CGL includes the n-type charge generation layer n-CGL, the thickness of the n-type charge generation layer n-CGL may be, for example, about 100 Å to about 1000 Å. If the charge generation unit CGL includes the p-type charge generation layer p-CGL, the thickness of the p-type charge generation layer p-CGL may be, for example, about 100 Å to about 1000 Å. If the thicknesses of the charge generation unit CGL, the n-type charge generation layer n-CGL, and the p-type charge generation layer p-CGL satisfy any of the above-described ranges, a satisfactory degree of the controlling properties of charge balance may be obtained.

Hereinafter, the relation between the p-type charge generation layer p-CGL of the charge generation unit CGL and the first hole transport region HTR1 of the first light emitting unit OL1 will be explained.

The p-type charge generation layer p-CGL of the charge generation unit CGL may have a first refractive index with respect to visible light. The p-type charge generation layer p-CGL of the charge generation unit CGL may have a first refractive index with respect to light in a wavelength region in a range of about 400 to about 700 nm. For example, the first refractive index may be in a range of about 1.78 to about 2.0. For example, the first refractive index may be in a range of about 1.79 to about 1.90. The first hole transport region HTR1 of the first light emitting unit OL1 may have a second refractive index with respect to visible light. The first hole transport region HTR1 of the first light emitting unit OL1 may have a second refractive index with respect to light in a wavelength region in a range of about 400 to about 700 nm. For example, the second refractive index may be in a range of about 1.50 to about 1.78. For example, the second refractive index may be in a range of about 1.70 to about 1.78.

The p-type charge generation layer p-CGL of the charge generation unit CGL may have a first-first refractive index with respect to blue light in a wavelength region of about 400 to about 500 nm, may have a first-second refractive index with respect to green light in a wavelength region of about 500 to about 600 nm, and may have a first-third refractive index with respect to red light in a wavelength region of about 600 to about 700 nm. For example, the first-first refractive index may be in a range of about 1.85 to about 1.95, the first-second refractive index may be in a range of about 1.80 to about 1.90, and the first-third refractive index may be in a range of about 1.75 to about 1.85. The first hole transport region HTR1 of the first light emitting unit OL1 may have a second-first refractive index with respect to blue light in a wavelength region of about 400 to about 500 nm, may have a second-second refractive index with respect to green light in a wavelength region of about 500 to about 600 nm, and may have a second-third refractive index with respect to red light in a wavelength region of about 600 to about 700 nm. For example, the second-first refractive index may be in a range of about 1.75 to about 1.85, the second-second refractive index may be in a range of about 1.70 to about 1.80, and the second-third refractive index may be in a range about 1.65 to about 1.75.

In an embodiment, with respect to any visible light, the first refractive index of the p-type charge generation layer p-CGL may be greater than the second refractive index of the first hole transport region HTR1. For example, the refractive index of the p-type charge generation layer p-CGL with respect to light of a wavelength of about 450 nm may be greater than the refractive index of the first hole transport region HTR1 with respect to light of a wavelength of about 450 nm. The first-first refractive index may be greater than the second-first refractive index, the first-second refractive index may be greater than the second-second refractive index, and the first-third refractive index may be greater than the second-third refractive index. In an embodiment, a relation between the first refractive index and the second refractive index with respect to any visible light may be represented by Mathematical Equation 1.

$$0.001 \leq n 1 - n 2 \leq 0.2 \qquad [ Mathematical Equation 1 ]$$

In Mathematical Equation 1, n1 may be the first refractive index, and n2 may be the second refractive index. For example, a difference between the first refractive index and the second refractive may be equal to or less than about 0.2. For example, a difference between the first-first refractive index and the second-first refractive index, a difference between the first-second refractive index and the second-second refractive index, and a difference between the first-third refractive index and the second-third refractive index may each be in a range of about 0.01 to about 0.15.

In an embodiment, with respect to any visible light, a first extinction coefficient of the p-type charge generation layer p-CGL may be greater than a second extinction coefficient of the first hole transport region HTR1. In an embodiment, a first extinction coefficient of the p-type charge generation layer p-CGL with respect to light with a wavelength of about 450 nm may be greater than a second extinction coefficient of the first hole transport region HTR1 with respect to light with a wavelength of about 450 nm. In an embodiment, a relation between the first extinction coefficient and the second extinction coefficient with respect to any visible light may be represented by Mathematical Equation 2.

$$0.0001 \leq k 1 - k 2 \leq 0.1 \qquad [ Mathematical Equation 2 ]$$

In Mathematical Equation 2, k1 may be the first extinction coefficient, and k2 may be the second extinction coefficient. For example, a difference between the first extinction coefficient and the second extinction coefficient may be equal to or less than about 0.2. For example, a difference between the first extinction coefficient and the second extinction coefficient with respect to any red light, a difference between the first extinction coefficient and the second extinction coefficient with respect to any green light, and a difference between the first extinction coefficient and the second extinction coefficient with respect to any blue light may each be in a range of about 0.0001 to about 0.05.

A second light emitting unit OL2 may be provided on the charge generation unit CGL. The second light emitting unit OL2 may include a second emission layer EML2 and a second electron transport region ETR2, stacked in that order. In an embodiment, the second light emitting unit OL2 may include a second hole transport region HTR2, a second emission layer EML2 and a second electron transport region ETR2, stacked in that order.

The second hole transport region HTR2 of the second light emitting unit OL2 may be provided on the charge generation unit CGL. The second hole transport region HTR2 may include at least one of a second hole injection layer HIL2, a second hole transport layer HTL2, a second emission auxiliary layer SE2, and a second electron blocking layer (not shown). The second emission layer EML2 of the second light emitting unit OL2 may be provided on the second hole transport region HTR2. The second emission layer EML2 may include a second red emission layer EML-R2 that overlaps a first light emitting region PXA-R, a second green emission layer EML-G2 that overlaps a second light emitting region PXA-G, and a second blue emission layer EML-B2 that overlaps a third light emitting region PXA-B. The second electron transport region ETR2 of the second light emitting unit OL2 may be provided on the second emission layer EML2. The second electron transport region ETR2 may include at least one of a second hole blocking layer (not shown), a second electron transport layer ETL1 and a second electron injection layer EIL1.

In embodiments, the second light emitting unit OL2 may include the same contents as described herein with respect to the first light emitting unit OL1. For example, the first hole transport region HTR1 may include a same content as the second hole transport region HTR2, and the first emission layer EML1 may include a same content as the second emission layer EML2, and the first electron transport region ETR1 may include a same content as the second electron transport region ETR2.

In FIG. 3B to FIG. 3D, the constituent elements constituting each of the first light emitting unit OL1 and the second light emitting unit OL2 are correspondingly shown, but the stacking structure of each of the first light emitting unit OL1 and the second light emitting unit OL2 is not limited to the drawings and may be provided in various combinations according to the display quality properties required for a light emitting element ED. For example, in the light emitting element ED of another embodiment, the second hole transport region HTR2 of the second light emitting unit OL2 may have a structure including second emission auxiliary layers SE-R2, SE-G2, and SE-B2, and the first hole transport region HTR1 of the first light emitting unit OL1 may have a structure not including first emission auxiliary layers SE-R1, SE-G1 and SE-B1. In other embodiments, the second electron transport region ETR2 of the second light emitting unit OL2 may have a structure including a second electron injection layer EIL2, and the first electron transport region ETR1 of the first light emitting unit OL1 may have a structure not including a first electron injection layer EIL1.

The second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second cathode EL2 may be a cathode, and if the first electrode EL₁ is a cathode, the second electrode EL2 may be an anode.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In an embodiment, the second electrode EL2 may have a multilayered structure including a reflective layer or a transflective layer formed using the above-described materials and a transparent conductive layer formed using ITO, IZO, ZnO, ITZO, etc. For example, the second electrode EL2 may include the aforementioned metal materials, combinations of two or more metal materials selected from the aforementioned metal materials, or oxides of the aforementioned metal materials.

Although not shown in the drawings, the second electrode EL2 may be electrically connected with an auxiliary electrode. If the second electrode EL2 is electrically connected with the auxiliary electrode, the resistance of the second electrode EL2 may decrease.

In an embodiment, the light emitting element may further include a capping layer CPL disposed on the second electrode EL2. The capping layer CPL may include a multilayer or a single layer.

In an embodiment, the capping layer CPL may include an organic layer or an inorganic layer. For example, if the capping layer CPL includes an inorganic material, the inorganic material may include an alkali metal compound such as LiF, an alkaline earth metal compound such as MgF₂, SiON, SiNₓ, SiO_{y}, etc.

For example, if the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., or may include an epoxy resin, or acrylate such as methacrylate. A capping layer CPL may include at least one of Compounds P1 to P5, but embodiments are not limited thereto.

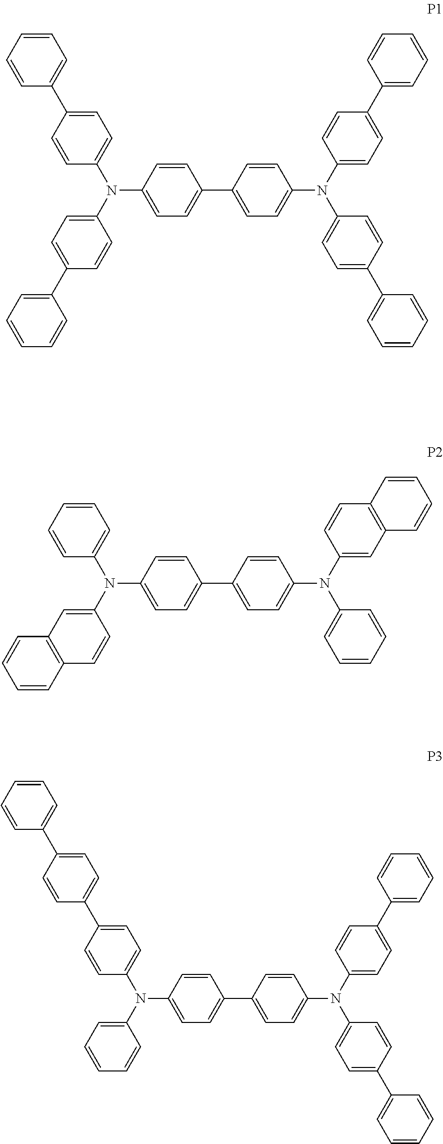 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

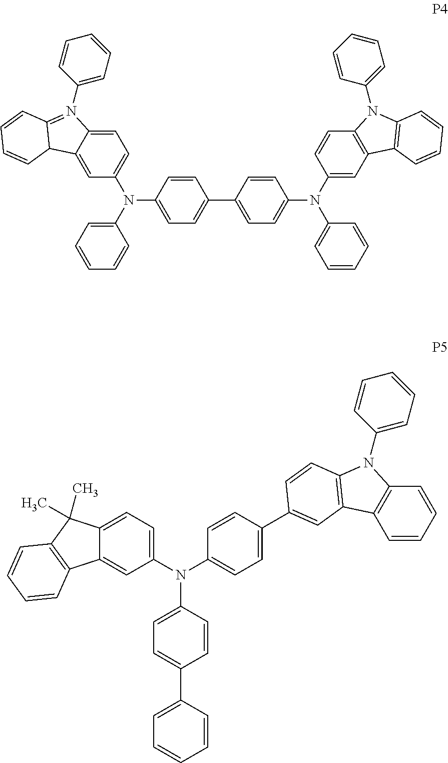

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

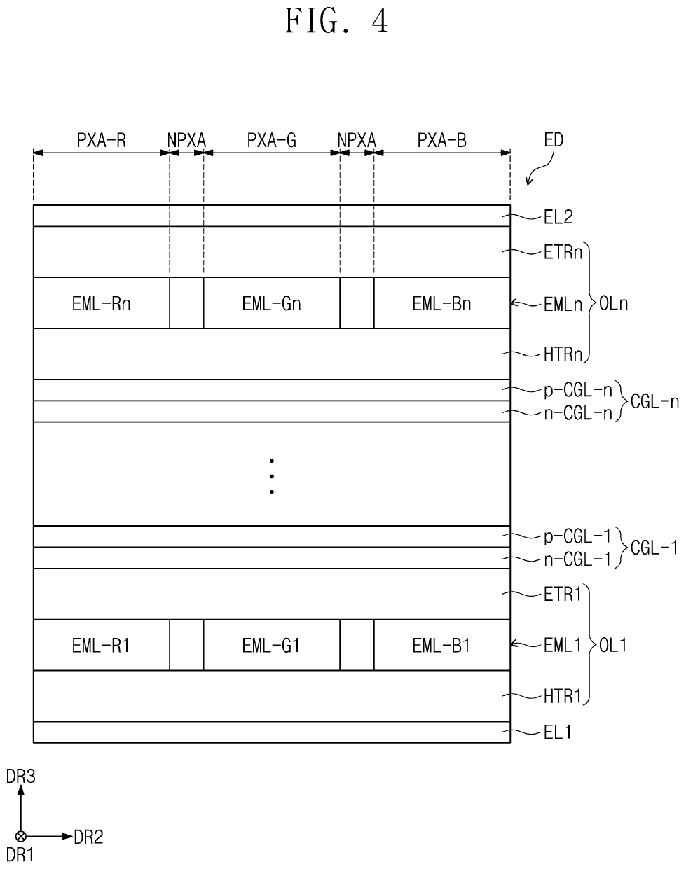

FIG. 4 is a schematic cross-sectional view of a light emitting element according to another embodiment.

The light emitting element ED of FIG. 4 is shown to be different from FIG. 3A to FIG. 3E at least in that the light emitting element ED includes n light emitting units OL1-OLn. In the description, n in FIG. 4 may be 3 or more.

Referring to FIG. 4, the light emitting element ED according to an embodiment may include a first electrode EL1, a second electrode EL2, n light emitting units OL1 to OLn stacked in a thickness direction between the first electrode EL1 and the second electrode EL2, and n−1 charge generation layers CGL-1 to CGL-n disposed between neighboring light emitting units OL1 to OLn. The first to n-th light emitting units OL1 to OLn may include first to n-th hole transport regions HTR1 to HTRn, first to n-th emission layers EML1 to EMLn, and first to n-th electron transport regions ETR1 to ETRn, respectively stacked in that order. The first to n-th emission layers EML1 to EMLn may respectively include first to n-th red emission layers EML-R1 to EML-Rn, first to n-th green emission layers EML-G1 to EML-Gn, and first to n-th blue emission layers EML-B1 to EML-Bn. Charge generation layers CGL-1 to CGL-n disposed between neighboring light emitting units OL1-OLn may respectively include p-type charge generation layers p-CGL-1 to p-CGL-n and n-type charge generation layers n-CGL-1 to n-CGL-n.

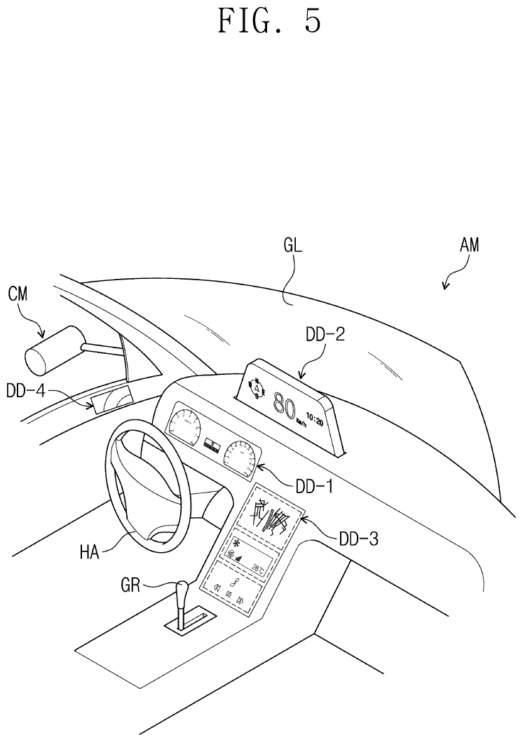

FIG. 5 is a diagram showing a vehicle in which a display device according to an embodiment is disposed.

Referring to FIG. 5, an electronic device according to an embodiment may include display devices DD-1, DD-2, DD-3, and DD-4 for a vehicle AM. At least one of the first to fourth display devices DD-1, DD-2, DD-3, and DD-4 may have a structure according to the display device DD according to an embodiment, as described above with reference to FIG. 1.

In FIG. 5, the first to fourth display devices DD-1, DD-2, DD-3, and DD-4 are shown as display devices disposed in the vehicle AM. However, this is only an illustration, and the first to fourth display devices DD-1, DD-2, DD-3, and DD-4 may be disposed in other transport means such as bicycles, motorcycles, trains, ships, and airplanes. In an embodiment, at least one of the first to fourth display devices DD-1, DD-2, DD-3, and DD-4 having a structure according to the display device DD may be included in personal computers, laptop computers, personal digital terminals, game consoles, portable electronic devices, televisions, monitors, external billboards, or the like. However, these are given as examples, and the display device may be included in other electronic devices.

At least one of the first to fourth display devices DD-1, DD-2, DD-3, and DD-4 may each independently include the light emitting element ED according to an embodiment, as described with reference to any of FIG. 2, FIG. 3A to FIG. 3E and FIG. 4.

Referring to FIG. 5, a vehicle AM may include a steering wheel HA and a gearshift GR for the operation of the vehicle AM. The vehicle AM may include a front window GL disposed to face a driver.

A first display device DD-1 may be disposed in a first region that overlaps the steering wheel HA. For example, the first display device DD-1 may be a digital cluster that displays the first information of the vehicle AM. The first information may include a first graduation showing the driving speed of the vehicle AM, a second graduation showing an engine speed (for example, revolutions per minute (RPM)), and a fuel state. First graduation and second graduation may be represented by digital images.

A second display device DD-2 may be disposed in a second region facing a driver's seat and overlapping the front window GL. The driver's seat may be a seat where the steering wheel HA is disposed. For example, the second display device DD-2 may be a head up display (HUD) showing the second information of the vehicle AM. The second display device DD-2 may be optically clear. The second information may include digital numbers showing the running speed of the vehicle AM and may further include information such as the current time. Although not shown in the drawings, in an embodiment, the second information of the second display device DD-2 may be displayed by being projected and onto the front window GL.

A third display device DD-3 may be disposed in a third region adjacent to the gearshift GR. For example, the third display device DD-3 may be a center information display (CID) for a vehicle, disposed between a driver's seat and a passenger seat and showing third information. The passenger seat may be a seat that is spaced apart from the driver's seat with the gearshift GR disposed therebetween. The third information may include information on road conditions (for example, navigation information), on playing music or radio, on playing a dynamic image (or image), on the temperature in the vehicle AM, or the like.

A fourth display device DD-4 may be disposed in a fourth region that is spaced apart from the steering wheel HA and the gearshift GR and adjacent to a side of the vehicle AM. For example, the fourth display device DD-4 may be a digital side-view mirror that displays fourth information. The fourth display device DD-4 may display an image external to the vehicle AM that is taken by a camera module CM disposed outside of the vehicle AM. The fourth information may include an image of the exterior of the vehicle AM.

The first to fourth information as described above are only presented as examples, and the first to fourth display devices DD-1, DD-2, DD-3, and DD-4 may further display information about the interior and the exterior of the vehicle. The first to fourth information may include information that is different from each other. However, embodiments are not limited thereto, and a part of the first to fourth information may include the same information as one another.

Hereinafter, a light emitting element according to an embodiment will be describe be described with reference to the Examples and the Comparative Examples described. The embodiments described below are only provided as illustrations to assist in understanding the disclosure, but the scope thereof not limited thereto.

### EXAMPLES AND COMPARATIVE EXAMPLES

### 1. Manufacture of Light Emitting Elements

### (Manufacture of Light Emitting Element (Example 1)

To manufacture a light emitting element according to an embodiment, as a first electrode, a glass substrate on which an ITO electrode of about 15 Ω/cm² (about 1200 Å) was formed (Corning Co.), was cut into a size of 50 mm×50 mm×0.5 mm, cleansed using ultrasonic waves using isopropyl alcohol and ultrapure water for about 5 minutes each, exposed to ultraviolet (UV) light for about 30 minutes and cleansed by exposing to ozone. The glass substrate was installed in a vacuum deposition apparatus.

On the first electrode, a first light emitting unit was formed. On the first electrode, a hole transport host of Compound 11 doped with a p-dopant (2%) of Compound P1 was deposited to about 10 nm, and the hole transport host of Compound 11 was deposited to about 30 nm to form a first hole transport region as a common layer. On the first hole transport region, a light emitting host of Compound E-2-21 doped with a light emitting dopant (2%) of Compound M-a11 was deposited to about 40 nm to overlap a first light emitting region to form a first red emission layer, on the first hole transport region, a light emitting host of Compound E-2-9 doped with a light emitting dopant (10%) of Compound M-a13 was deposited to about 30 nm to overlap a second light emitting region to form a first green emission layer, and on the first hole transport region, a light emitting host of Compound E19 doped with a light emitting dopant (1%) of Compound BD was deposited to about 30 nm to overlap a third light emitting region to form a first blue emission layer, thereby forming a first emission layer as a pattern layer. An electron transport host of Compound ET37 was deposited to about 30 nm to form a first electron transport region as a common layer.

An electron transport host of Compound ET37 doped with a Yb metal material dopant (5%) was deposited to about 10 nm to form an n-type charge generation layer as a common layer. On the first electron transport region, a charge generation unit was formed. On the first electron transport region, a hole transport host of Compound H-1-2 doped with a p-dopant (4%) of Compound P1 was deposited to about 10 nm, and the hole transport host of Compound H-1-2 was deposited to about 50 nm to form a p-type charge generation layer as a common layer.

On the p-type charge generation layer, a second light emitting unit was formed. On the p-type charge generation layer, the second red emission layer, the second green emission layer and the second blue emission layer of the second emission layer were formed using the same materials as the first red emission layer, the first green emission layer and the first blue emission layer of the first emission layer to a same thicknesses, respectively. An electron transport host of Compound ET38 was deposited to about 30 nm to form a second electron transport region as a common layer.

On the second electron transport region, Ag:Mg (10%) was deposited to form a second electrode with a thickness of about 90 Å to manufacture a light emitting element. All layers were formed by a vacuum deposition method. The hole transport host of Compound 11 is Compound 11 from among the compounds in Compound Group 1, the hole transport host of Compound H-1-2 is Compound H-1-2 from among the compounds in Compound Group H, the light emitting hosts of Compounds E-2-21 and E-2-9 are Compounds E-2-21 and E-2-9 Compound from among the compounds in Group E-2, the light emitting dopants of Compound M-a11 and M-a13 are the phosphorescent dopant Compounds M-a11 and M-a13 as described above, the light emitting host of Compound E19 is the fluorescence host Compound E19 as described above, and Compounds ET37 and ET38 are Compounds ET37 and ET38 as described above.

### (Manufacture of Light Emitting Element of Example 2)

A light emitting element of Example 2 was manufactured by applying the same method for manufacturing the stacking structure of the light emitting element of Example 1. In comparison to the light emitting element of Example 1, the light emitting element of Example 2 was manufactured by the same method except for using a different compound for forming the first hole transport region.

The first hole transport region of the light emitting element of Example 2 was formed as a common layer by depositing on the first electrode a hole transport host of Compound 14 doped with a p-dopant (2%) of Compound P1 to about 10 nm and depositing the hole transport host of Compound 14 to about 30 nm.

The hole transport host of Compound 14 may be Compound 14 among the compounds in the above-described Compound Group 1.

### (Manufacture of Light Emitting Element of Example 3)

A light emitting element of Example 3 was manufactured by applying the same method for manufacturing the stacking structure of the light emitting element of Example 1. In comparison to the light emitting element of Example 1, the light emitting element of Example 3 was manufactured by the same method except for using a different compound for forming the first hole transport region.

The first hole transport region of the light emitting element of Example 3 was formed as a common layer by depositing on the first electrode a hole transport host of Compound 18 doped with a p-dopant (2%) of Compound P1 to about 10 nm and depositing the hole transport host of Compound 18 to about 30 nm.

The hole transport host of Compound 18 may be Compound 18 among the compounds in the above-described Compound Group 1.

### (Manufacture of Light Emitting Element of Comparative Example 1)

A light emitting element of Comparative Example 1 was manufactured by applying the same method for manufacturing the stacking structure of the light emitting element of Example 1. In comparison to the light emitting element of Example 1, the light emitting element of Comparative Example 1 was manufactured by the same method except for using a different compound for forming the first hole transport region and a different compound for forming the p-type charge generation layer.

The first hole transport region of the light emitting element of Comparative Example 1 was formed as a common layer by depositing on the first electrode a hole transport host of H-1-20 doped with a p-dopant (2%) of P1 to about 10 nm and depositing the hole transport host of H-1-20 to about 30 nm. The p-type charge generation layer of the light emitting element of Comparative Example 1 was formed as a common layer by depositing on the first electron transport region a hole transport host of H-1-1 doped with a p-dopant (2%) of P1 to about 10 nm and depositing the hole transport host of H-1-1 to about 50 nm.

The hole transport hosts of Compounds H-1-1 and H-1-20 may be Compounds H-1-1 and H-1-20 among the compounds in the above-described Compound Group H.

### (Manufacture of Light Emitting Element of Comparative Example 2)

A light emitting element of Comparative Example 2 was manufactured by applying the same method for manufacturing the stacking structure of the light emitting element of Example 1. Compared to the light emitting element of Example 1, the light emitting element of Comparative Example 2 was manufactured by the same method except for using a different compound for forming the first hole transport region and a different compound for forming the p-type charge generation layer.

The first hole transport region of the light emitting element of Comparative Example 2 was formed as a common layer by depositing on the first electrode a hole transport host of H-1-2 doped with a p-dopant (2%) of Compound P1 to about 10 nm and depositing the hole transport host of H-1-2 to about 30 nm. The p-type charge generation layer of the light emitting element of Comparative Example 2 was formed as a common layer by depositing on the first electron transport region a hole transport host of Compound 18 doped with a p-dopant (2%) of P1 to about 10 nm and depositing the hole transport host of Compound 18 to about 50 nm.

The hole transport host of Compound H-1-2 may be Compound H-1-2 among the compounds in the above-described Compound Group H. The hole transport host of Compound 18 may be Compound 18 among the compounds in the above-described Compound Group 1.

The compounds used for the manufacture of the light emitting elements of the Examples and the light emitting elements of the Comparative Examples are shown below. The materials were used for the manufacture of the elements after purchasing commercial products and purifying by sublimation.

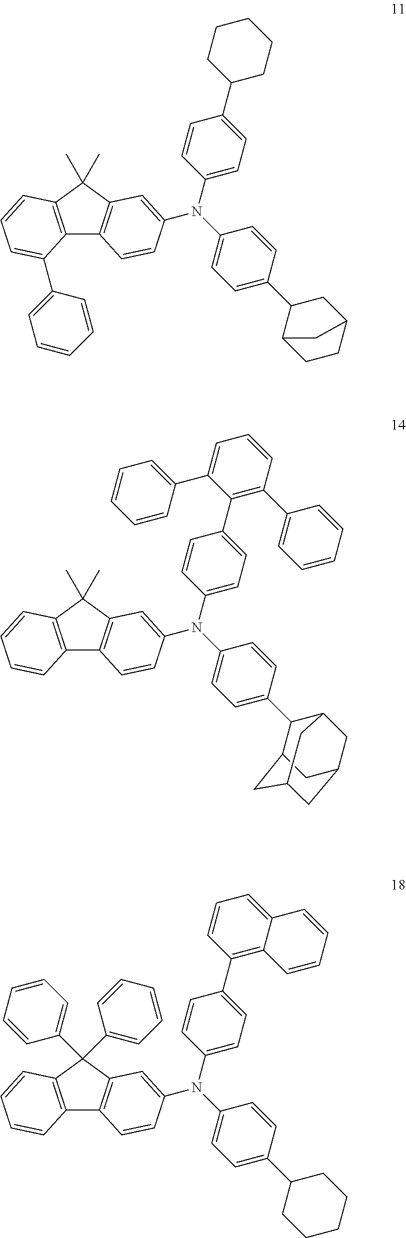 [SMILES: CC1(C)c2cc(N(c3ccc(C4CCCCC4)cc3)c3ccc(C4CC5CCC4C5)cc3)ccc2-c2c(-c3ccccc3)cccc21 ; CC1(C)c2ccccc2-c2ccc(N(c3ccc(-c4c(-c5ccccc5)cccc4-c4ccccc4)cc3)c3ccc(C4C5CC6CC(C5)CC4C6)cc3)cc21 ; c1ccc(C2(c3ccccc3)c3ccccc3-c3ccc(N(c4ccc(-c5cccc6ccccc56)cc4)c4ccc(C5CCCCC5)cc4)cc32)cc1]

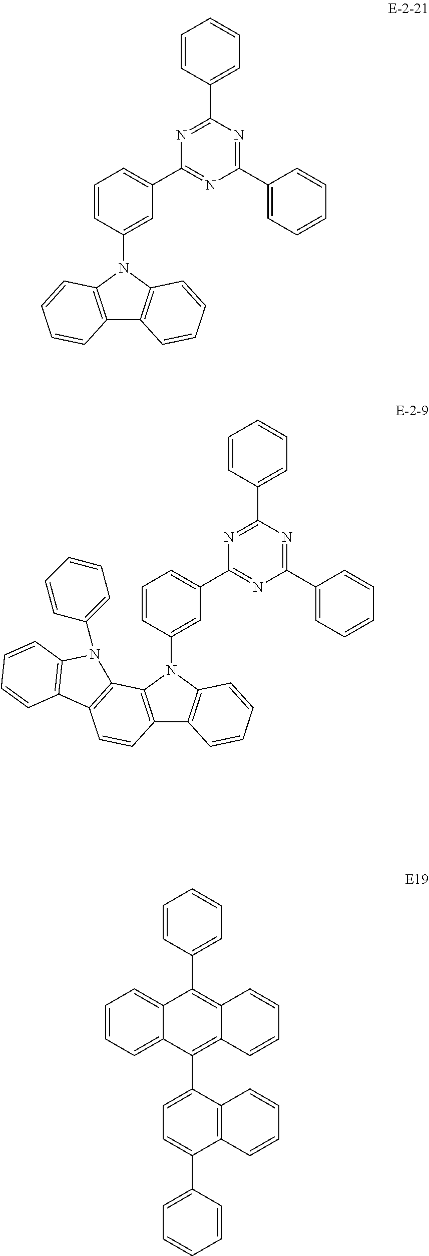

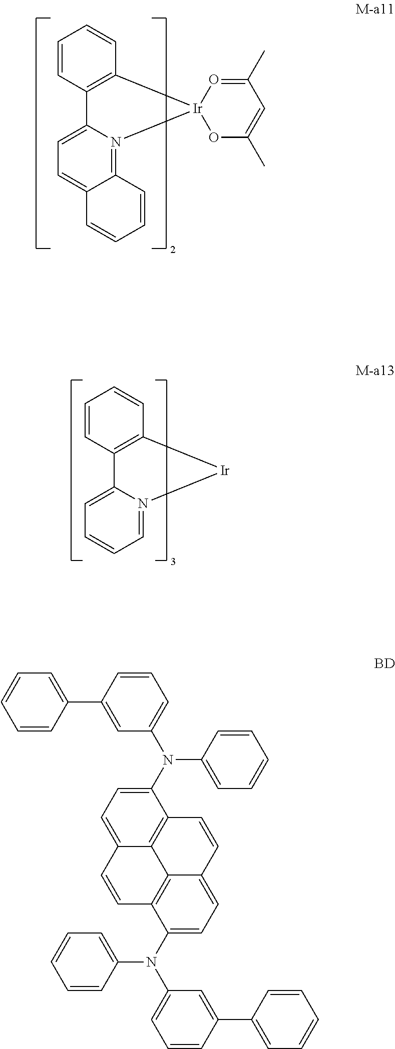

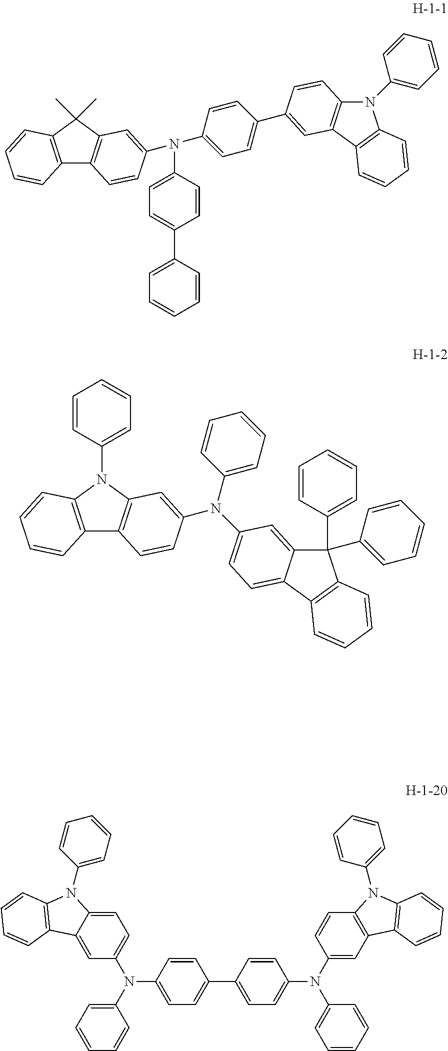 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

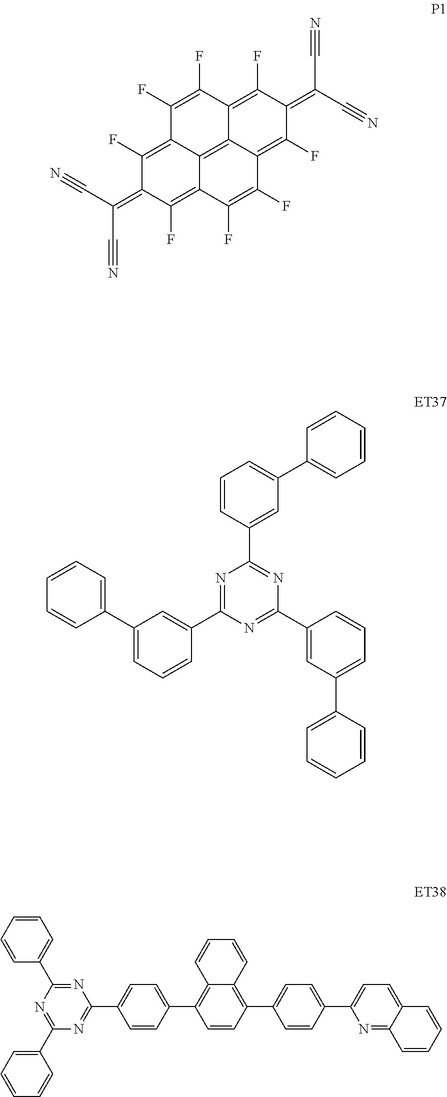 [SMILES: N#CC(C#N)=c1c(F)c2c(F)c(F)c3c(F)c(=C(C#N)C#N)c(F)c4c(F)c(F)c(c1F)c2c34 ; c1ccc(-c2cccc(-c3nc(-c4cccc(-c5ccccc5)c4)nc(-c4cccc(-c5ccccc5)c4)n3)c2)cc1 ; c1ccc(-c2nc(-c3ccccc3)nc(-c3ccc(-c4ccc(-c5ccc(-c6ccc7ccccc7n6)cc5)c5ccccc45)cc3)n2)cc1]

2. Evaluation of Properties on p-Type Charge Generation Layers and First Hole Transport Regions

The refractive indexes of the first hole transport region HTR1 and the p-type charge generation layer p-CGL of each of Example 1 to Example 3, Comparative Example 1 and Comparative Example 2 were measured. When measuring the refractive index, blue light of a wavelength of about 450 nm, green light of a wavelength of about 530 nm and red light of a wavelength of about 620 nm were used. In Table 1, the refractive index values of the first hole transport region and the p-type charge generation layer of each of Example 1 to Example 3, Comparative Example 1 and Comparative Example 2, in accordance with a light wavelength are shown.

TABLE 1

| | | Refractive index | | |
|---|---|---|---|---|
| | | Blue light | Green light | Red light |
| | | (450 nm) | (530 nm) | (620 nm) |
| Example 1 | HTR1 | 1.78 | 1.73 | 1.71 |
| | (material: Compound 11) | | | |
| | p-CGL | 1.89 | 1.83 | 1.79 |
| | (material: H-1-2) | | | |
| Example 2 | HTR1 | 1.81 | 1.76 | 1.75 |
| | (material: Compound 14) | | | |
| | p-CGL | 1.89 | 1.83 | 1.79 |
| | (material: H-1-2) | | | |
| Example 3 | HTR1 | 1.74 | 1.71 | 1.69 |
| | (material: Compound 18) | | | |
| | p-CGL | 1.89 | 1.83 | 1.79 |
| | (material: H-1-2) | | | |
| Comparative | HTR1 | 2.08 | 1.98 | 1.92 |
| Example 1 | (material: H-1-20) | | | |
| | p-CGL | 2.07 | 1.95 | 1.91 |
| | (material: H-1-1) | | | |
| Comparative | HTR1 | 1.89 | 1.83 | 1.79 |
| Example 2 | (material: H-1-2) | | | |
| | p-CGL | 1.74 | 1.71 | 1.69 |
| | (material: Compound 18) | | | |

Referring to Table 1, the first refractive index of the p-type charge generation layer is greater than the second refractive index of the first hole transport region in each of Example 1 to Example 3. With respect to each of the blue light of a wavelength of about 450 nm, the green light of a wavelength of about 530 nm and the red light of a wavelength of about 620 nm, the first refractive index of the p-type charge generation layer is greater than the second refractive index of the first hole transport region in each of Example 1 to Example 3. For example, with respect to each of the blue light, green light and red light, a difference between the first refractive index and the second refractive index is in a range of about 0.001 to about 0.2. In contrast to that difference, the first refractive index of the p-type charge generation layer is smaller than the second refractive index of the first hole transport region in each of Comparative Example 1 and Comparative Example 2. With respect to each of the blue light of a wavelength of about 450 nm, the green light of a wavelength of about 530 nm and the red light of a wavelength about 620 nm, it can be found that the first refractive index of the p-type charge generation layer is smaller than the second refractive index of the first hole transport region in each of Comparative Example 1 and Comparative Example 2.

### 3. Evaluation of Properties of Light Emitting Elements

The element efficiency and element lifetime of the light emitting elements of Example 1 to Example 3, Comparative Example 1 and Comparative Example 2 were evaluated. In Table 2, the evaluation results of the light emitting elements of Example 1 to Example 3, Comparative Example 1 and Comparative Example 2 are shown. In order to evaluate the properties of the light emitting elements manufactured in Example 1 to Example 3, Comparative Example 1 and Comparative Example 2, top emission efficiency (Cd/A/y) with respect to blue light, green light and red light was measured using a luminescence meter SR-3AR, and time consumed for reducing initial luminance to 95% was measured with respect to blue light, green light and red light as relative lifetime (T95), and relative lifetime based on the light emitting element of the Comparative Example 1 was calculated. The results are shown in Table 2.

TABLE 2

| | Top emission efficiency (Cd/A/y) | | | Relative lifetime (T95) | | |
|---|---|---|---|---|---|---|
| | Blue light | Green light | Red light | Blue light | Green light | Red light |
| | (450 nm) | (530 nm) | (620 nm) | (450 nm) | (530 nm) | (620 nm) |
| Example 1 | 114% | 102% | 98% | 110% | 150% | 100% |
| Example 2 | 120% | 100% | 100% | 105% | 110% | 100% |
| Example 3 | 110% | 100% | 105% | 100% | 108% | 110% |
| Comparative | 100% | 100% | 100% | 100% | 100% | 100% |
| Example 1 | | | | | | |
| Comparative | 100% | 99% | 101% | 97% | 96% | 98% |
| Example 2 | | | | | | |

Referring to the results of Table 2, the light emitting elements according to an embodiment were confirmed to show improved lifetime characteristics with respect to blue light, green light, and red light in comparison to the light emitting elements of the Example Compounds. In an embodiment, the light emitting elements were confirmed to show high emission efficiency with respect to blue light, green light, and red light in comparison to the light emitting elements of the Comparative Examples. Referring to Table 1 and Table 2. In the cases of the light emitting elements of Example 1 to Example 3, the first compound that is a tertiary amine compound including a cycloalkyl moiety is included in the first hole transport region or the p-type charge generation layer. In an embodiment, in the cases of the light emitting elements, the first refractive index of the p-type charge generation layer is greater than the second refractive index of the first hole transport region. Accordingly, increasing effects of emission efficiency can be accomplished in a short wavelength region of visible light, for example, a blue light wavelength region, in which the realization of color is relatively difficult. In an embodiment, long lifetime and high element efficiency can be achieved.

In Comparative Example 1, the first compound is not included in the first hole transport region or the p-type charge generation layer, and the first refractive index of the p-type charge generation layer is smaller than the second refractive index of the first hole transport region. Accordingly, the light emitting element of Comparative Example 1 is thought to have degraded lifetime characteristics and emission efficiency with respect to blue light, green light, and red light in contrast to the Examples.

In Comparative Example 2, the first compound is included in the p-type charge generation layer, but the first refractive index of the p-type charge generation layer is smaller than the second refractive index of the first hole transport region. Accordingly, the light emitting element of Comparative Example 2 is thought to have degraded lifetime characteristics and emission efficiency with respect to blue light, green light, and red light in contrast to the Examples.

According to an embodiment, a tandem light emitting element that includes multiple light emitting stacks may include a hole transport region having low refractive index properties, and accordingly, emission efficiency may be maximized, and the emission efficiency and element lifetime of the light emitting element may be improved.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

1. A light emitting element comprising:
a first electrode;
a first light emitting unit disposed on the first electrode;
a charge generation unit disposed on the first light emitting unit;
a second light emitting unit disposed on the charge generation unit; and
a second electrode disposed on the second light emitting unit, wherein
the first light emitting unit comprises:
a first hole transport region disposed on the first electrode;
a first emission layer disposed on the first hole transport region; and
a first electron transport region disposed on the first emission layer,
the charge generation unit comprises:
an n-type charge generation layer disposed on the first light emitting unit; and
a p-type charge generation layer disposed on the n-type charge generation layer,
at least one of the p-type charge generation layer and the first hole transport region each independently comprises a tertiary amine compound comprising a cycloalkyl moiety, and
a first refractive index of the p-type charge generation layer with respect to a visible light is greater than a second refractive index of the first hole transport region with respect to the visible light.

2. The light emitting element of claim 1, wherein
the first refractive index is in a range of about 1.78 to about 2.0, and
the second refractive index is in a range of about 1.50 to about 1.78.

3. The light emitting element of claim 1, wherein a relation between the first refractive index and the second refractive index is represented by Mathematical Equation 1:
$$0.001 \leq n 1 - n 2 \leq 0.2 \qquad [ Mathematical Equation 1 ]$$
wherein in Mathematical Equation 1,
n1 is the first refractive index, and
n2 is the second refractive index.

4. The light emitting element of claim 1, wherein a first extinction coefficient of the p-type charge generation layer is greater than a second extinction coefficient of the first hole transport region.

5. The light emitting element of claim 4, wherein the relation between the first extinction coefficient and the second extinction coefficient is represented by the following Mathematical Equation 2:
$$0.0001 \leq k 1 - k 2 \leq 0.1 \qquad [ Mathematical Equation 2 ]$$
wherein in Mathematical Equation 2,
k1 is the first extinction coefficient, and
k2 is the second extinction coefficient.

6. The light emitting element of claim 1, wherein the tertiary amine compound is represented by Formula 1: 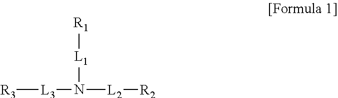
wherein in Formula 1,
L₁, L₂, and L₃ are each independently a direct linkage, a substituted or unsubstituted arylene group of 6 to 30 ring-forming carbon atoms, a substituted or unsubstituted heteroarylene group of 2 to 30 ring-forming carbon atoms, or a substituted or unsubstituted cycloalkylene group of 5 to 30 ring-forming carbon atoms,
R₁ is a substituted or unsubstituted cycloalkyl group of 5 to 30 carbon atoms,
R₂ is a hydrogen atom, a deuterium atom, a halogen atom, a cyano group, a hydroxyl group, a silyl group, a substituted or unsubstituted alkyl group of 1 to 20 carbon atoms, a substituted or unsubstituted cycloalkyl group of 5 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, and
R₃ is a group represented by Formula 2: 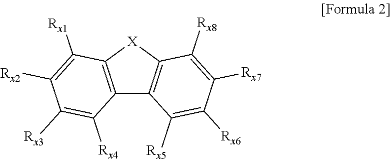
wherein in Formula 2,
X is C(R_{y1})(R_{y2}), N(R_{y3}), O, or S,
Rₓ₁ to Rₓ₈ and R_{y1} to R_{y3} are each independently a hydrogen atom, a deuterium atom, a halogen atom, a cyano group, a hydroxyl group, a substituted or unsubstituted alkyl group of 1 to 20 carbon atoms, a substituted or unsubstituted cycloalkyl group of 5 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring,
except that one of Rₓ₁ to Rₓ₈ is a position connected with Formula 1.

7. The light emitting element of claim 6, wherein R₁ is a group represented by one of Formula 3-1 to Formula 3-5: 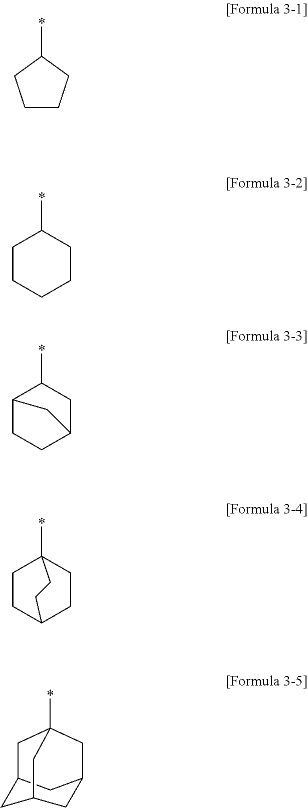 [SMILES: *C1CCCC1 ; *C1CCCCC1 ; *C1CC2CCC1C2 ; *C12CCC(CC1)CC2 ; *C12CC3CC(CC(C3)C1)C2]
wherein in Formula 3-1 to Formula 3-5, 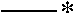 [SMILES: *C]
is a position connected to L₁ in Formula 1, and
at least one hydrogen atom is optionally substituted with a deuterium atom.

8. The light emitting element of claim 6, wherein the first hole transport region comprises the compound represented by Formula 1.

9. The light emitting element of claim 1, wherein the first hole transport region comprises at least one compound selected from Compound Group 1:

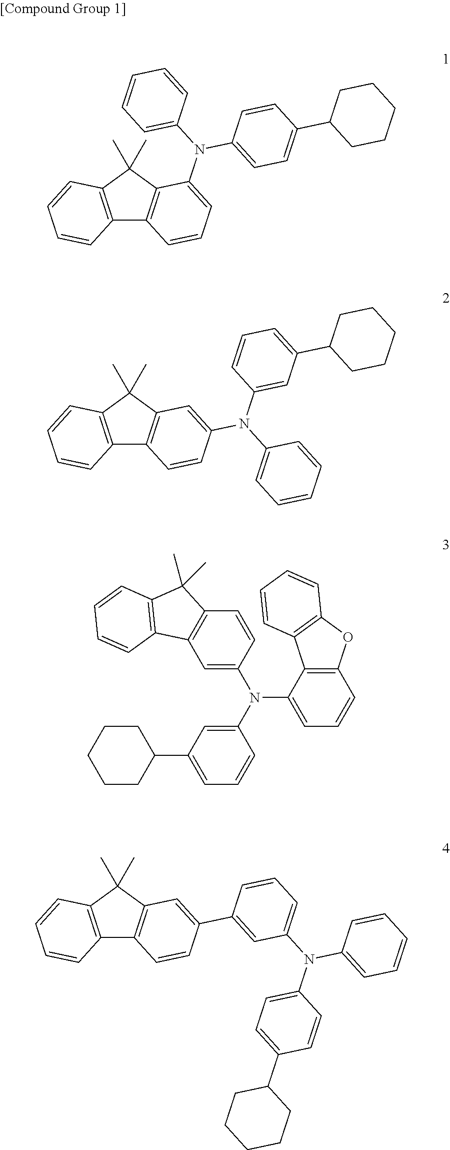 [SMILES: CC1(C)c2ccccc2-c2cccc(N(c3ccccc3)c3ccc(C4CCCCC4)cc3)c21 ; CC1(C)c2ccccc2-c2ccc(N(c3ccccc3)c3cccc(C4CCCCC4)c3)cc21 ; CC1(C)c2ccccc2-c2cc(N(c3cccc(C4CCCCC4)c3)c3cccc4oc5ccccc5c34)ccc21 ; CC1(C)c2ccccc2-c2ccc(-c3cccc(N(c4ccccc4)c4ccc(C5CCCCC5)cc4)c3)cc21]

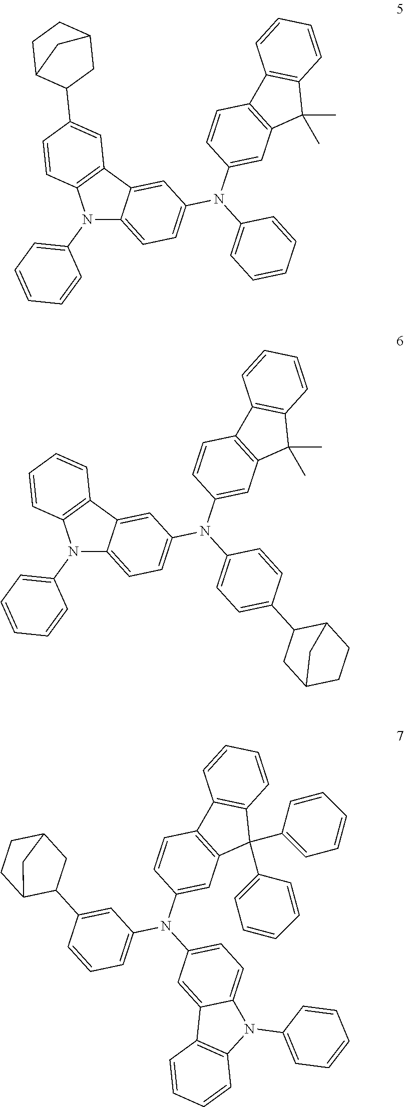 [SMILES: CC1(C)c2ccccc2-c2ccc(N(c3ccccc3)c3ccc4c(c3)c3cc(C5CC6CCC5C6)ccc3n4-c3ccccc3)cc21 ; CC1(C)c2ccccc2-c2ccc(N(c3ccc(C4CC5CCC4C5)cc3)c3ccc4c(c3)c3ccccc3n4-c3ccccc3)cc21 ; c1ccc(-n2c3ccccc3c3cc(N(c4cccc(C5CC6CCC5C6)c4)c4ccc5c(c4)C(c4ccccc4)(c4ccccc4)c4ccccc4-5)ccc32)cc1]

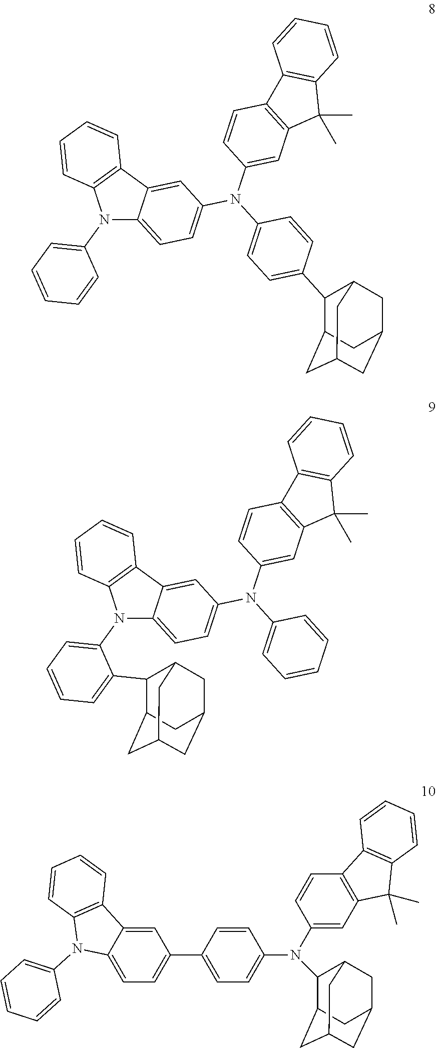

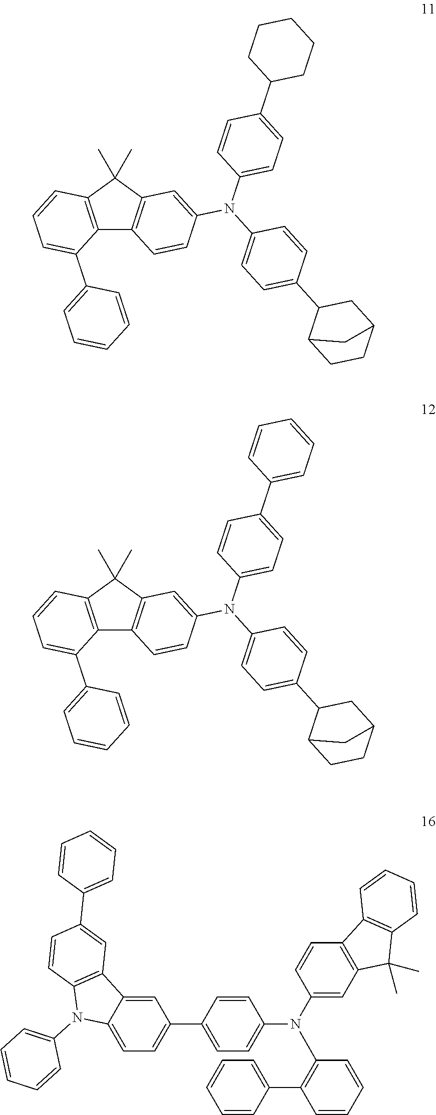 [SMILES: CC1(C)c2cc(N(c3ccc(C4CCCCC4)cc3)c3ccc(C4CC5CCC4C5)cc3)ccc2-c2c(-c3ccccc3)cccc21 ; CC1(C)c2cc(N(c3ccc(-c4ccccc4)cc3)c3ccc(C4CC5CCC4C5)cc3)ccc2-c2c(-c3ccccc3)cccc21 ; CC1(C)c2ccccc2-c2ccc(N(c3ccc(-c4ccc5c(c4)c4cc(-c6ccccc6)ccc4n5-c4ccccc4)cc3)c3ccccc3-c3ccccc3)cc21]

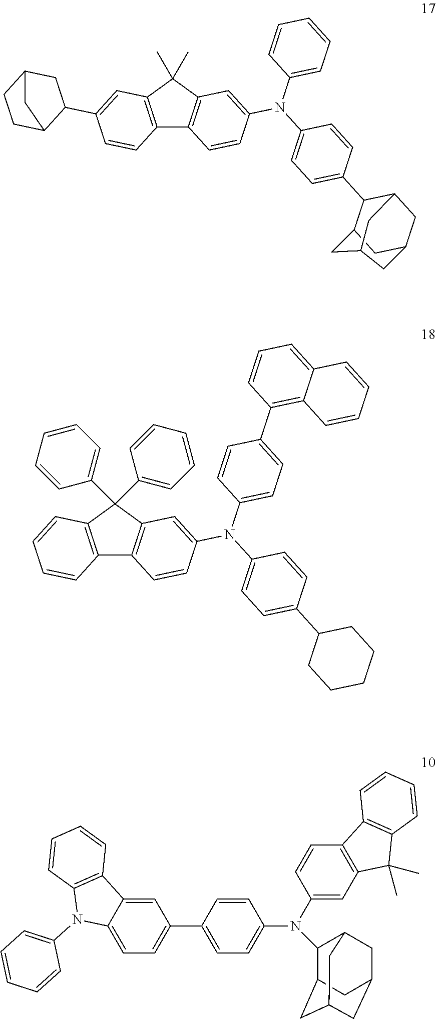 [SMILES: CC1(C)c2cc(C3CC4CCC3C4)ccc2-c2ccc(N(c3ccccc3)c3ccc(C4C5CC6CC(C5)CC4C6)cc3)cc21 ; c1ccc(C2(c3ccccc3)c3ccccc3-c3ccc(N(c4ccc(-c5cccc6ccccc56)cc4)c4ccc(C5CCCCC5)cc4)cc32)cc1 ; CC1(C)c2ccccc2-c2ccc(N(c3ccc(-c4ccc5c(c4)c4ccccc4n5-c4ccccc4)cc3)C3C4CC5CC(C4)CC3C5)cc21]

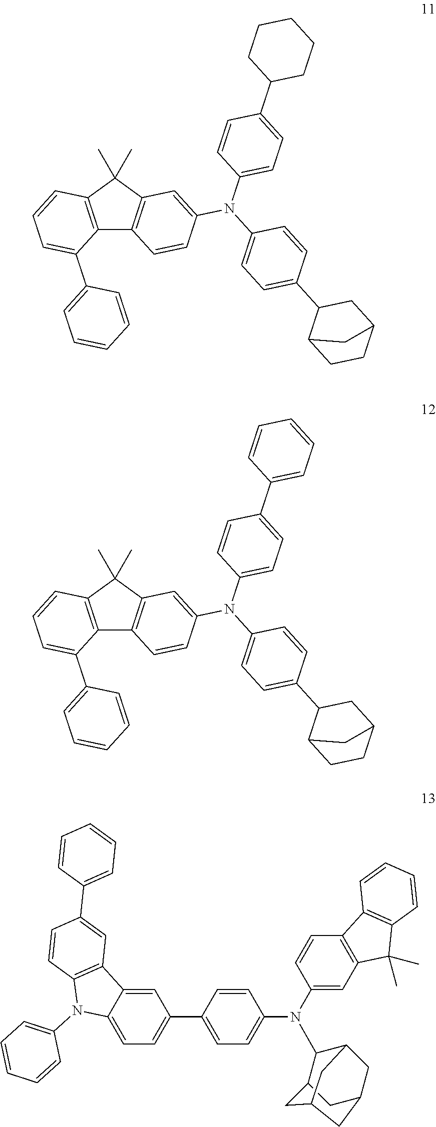 [SMILES: CC1(C)c2cc(N(c3ccc(C4CCCCC4)cc3)c3ccc(C4CC5CCC4C5)cc3)ccc2-c2c(-c3ccccc3)cccc21 ; CC1(C)c2cc(N(c3ccc(-c4ccccc4)cc3)c3ccc(C4CC5CCC4C5)cc3)ccc2-c2c(-c3ccccc3)cccc21 ; CC1(C)c2ccccc2-c2ccc(N(c3ccc(-c4ccc5c(c4)c4cc(-c6ccccc6)ccc4n5-c4ccccc4)cc3)C3C4CC5CC(C4)CC3C5)cc21]

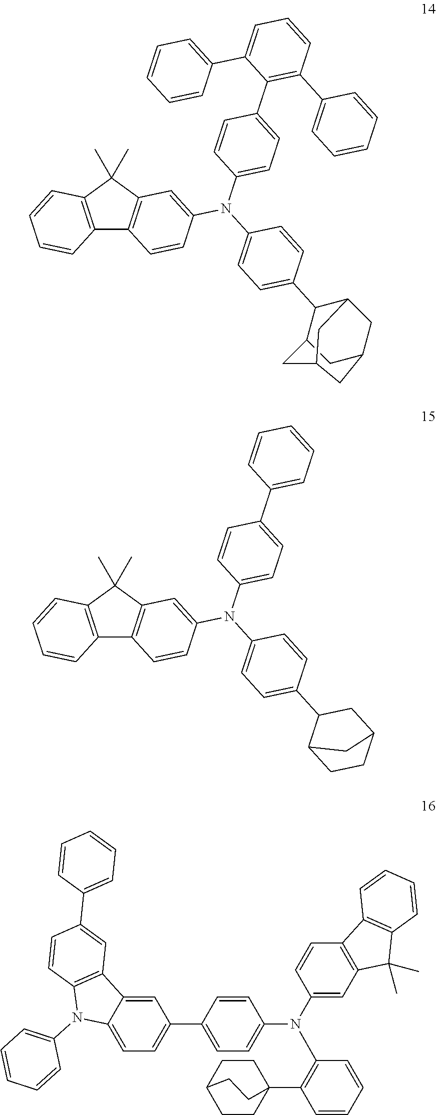 [SMILES: CC1(C)c2ccccc2-c2ccc(N(c3ccc(-c4c(-c5ccccc5)cccc4-c4ccccc4)cc3)c3ccc(C4C5CC6CC(C5)CC4C6)cc3)cc21 ; CC1(C)c2ccccc2-c2ccc(N(c3ccc(-c4ccccc4)cc3)c3ccc(C4CC5CCC4C5)cc3)cc21 ; CC1(C)c2ccccc2-c2ccc(N(c3ccc(-c4ccc5c(c4)c4cc(-c6ccccc6)ccc4n5-c4ccccc4)cc3)c3ccccc3C34CCC(CC3)CC4)cc21]

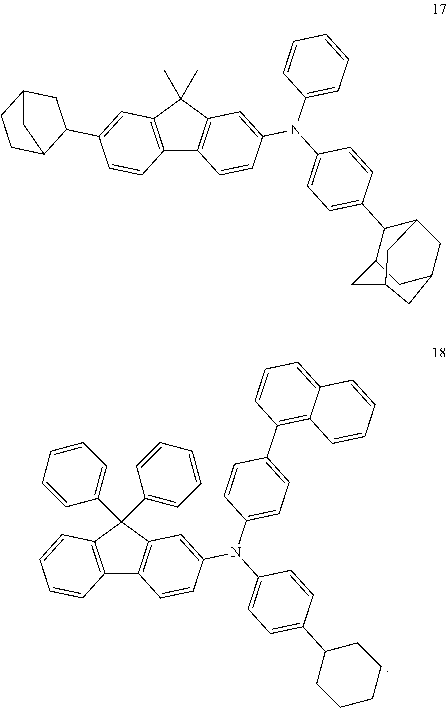 [SMILES: CC1(C)c2cc(C3CC4CCC3C4)ccc2-c2ccc(N(c3ccccc3)c3ccc(C4C5CC6CC(C5)CC4C6)cc3)cc21 ; c1ccc(C2(c3ccccc3)c3ccccc3-c3ccc(N(c4ccc(-c5cccc6ccccc56)cc4)c4ccc(C5CCCCC5)cc4)cc32)cc1]

10. The light emitting element of claim 1, wherein the first emission layer comprises:
a first red emission layer that overlaps a first light emitting region;
a first green emission layer that overlaps a second light emitting region; and
a first blue emission layer that overlaps a third light emitting region.

11. The light emitting element of claim 1, wherein the second light emitting unit comprises:
a second emission layer disposed on the charge generation unit; and
a second electron transport region disposed on the second emission layer.

12. The light emitting element of claim 11, wherein the second emission layer comprises:
a second red emission layer that overlaps a first light emitting region;
a second green emission layer that overlaps a second light emitting region; and
a second blue emission layer that overlaps a third light emitting region.

13. A display device comprising:
a base layer;
a circuit layer disposed on the base layer; and
a display device layer disposed on the circuit layer and comprising a light emitting element, wherein
the light emitting element comprises:
a first electrode;
a first light emitting unit disposed on the first electrode;
a charge generation unit disposed on the first light emitting unit;
a second light emitting unit disposed on the charge generation unit; and
a second electrode disposed on the second light emitting unit,
the first light emitting unit comprises:
a first hole transport region disposed on the first electrode;
a first emission layer disposed on the first hole transport region; and
a first electron transport region disposed on the first emission layer,
the charge generation unit comprises:
an n-type charge generation layer disposed on the first light emitting unit; and
a p-type charge generation layer disposed on the n-type charge generation layer,
at least one of the p-type charge generation layer and the first hole transport region comprises a tertiary amine compound comprising a cycloalkyl moiety, and
a first refractive index of the p-type charge generation layer with respect to a visible light is greater than a second refractive index of the first hole transport region with respect to the visible light.

14. The display device of claim 13, wherein
the base layer comprises:
a first light emitting region, a second light emitting region, and a third light emitting region, which are separated from each other in a plan view, and
a peripheral region defined between the first to third light emitting regions,
the display device layer comprises a pixel definition layer that overlaps the peripheral region and defines opening parts therein,
the opening parts overlap each of the first to third light emitting regions, and
the first emission layer is disposed in the opening parts.

15. The display device of claim 14, wherein the first emission layer comprises:
a first red emission layer that overlaps the first light emitting region;
a first green emission layer that overlaps the second light emitting region; and
a first blue emission layer that overlaps the third light emitting region.

16. The display device of claim 15, wherein the light emitting element comprises:
a first light emitting element comprising the first red emission layer and emitting red light;
a second light emitting element comprising the first green emission layer and emitting green light; and
a third light emitting element comprising the first blue emission layer and emitting blue light.

17. The display device of claim 16, wherein refractive indexes of the p-type charge generation layer with respect to the red light, the green light and the blue light are respectively greater than refractive indexes of the first hole transport region with respect to the red light, the green light, and the blue light.

18. The display device of claim 16, wherein extinction coefficients of the p-type charge generation layer with respect to the red light, the green light and the blue light are respectively greater than extinction coefficients of the first hole transport region with respect to the red light, the green light, and the blue light.

19. The display device of claim 14, wherein the first electrode, the first hole transport region, the first electron transport region, and the second electrode are provided as common layers in each of the first light emitting region, the second light emitting region, and the third light emitting region.

20. The display device of claim 14, wherein the n-type charge generation layer and the p-type charge generation layer are provided as common layers in each of the first light emitting region, the second light emitting region, and the third light emitting region.
